(19) United States
(12) Patent Application Publication
(10) Pub. No.: US 2015/0207485 A1
(43) Pub. Date: Jul. 23, 2015

(54) RC network

(71) Applicants: Yen Wei Hsu, Taipei (TW); Whei-Chyou Wu, Fremont, CA (US)

(72) Inventors: Yen Wei Hsu, Taipei (TW); Whei-Chyou Wu, Fremont, CA (US)

(21) Appl. No.: 14/158,869

(22) Filed: Jan. 20, 2014

(51) Int. Cl. H03H 7/01; H03H 7/19; H03H 7/06

(52) U.S. Cl. CPC H03H 7/06; H03H 7/17; H03H 7/0138; H03H 7/19

(57) ABSTRACT

The present invention is related to a variable resistor and a variable capacitor having damping capabilities, more particularly, to a RC network having damping capability and phase shift capability constructed by the variable resistor and the variable capacitor.

### BACKGROUND OF THE INVENTION

1. Field of the Invention

The present invention is related to a variable resistor and a variable capacitor having damping capabilities, more particularly, to a RC network having damping capability and phase shift capability constructed by the variable resistor and the variable capacitor.

2. Description of Related Art

The following is a brief review about a prior-art damper formed by a PDR, a ZDR, and a NDR electrically connected in series with each other. For any RLC circuit can be expressed by two first-order differential equations as followed:

$$\{ \begin{matrix}\frac{d x}{d t} = y - F ( x ) \\ \frac{d y}{d t} = - g ( x )\end{matrix} \qquad ( 1 )$$

of which x and y are state variables of which one is current and the other one is voltage and F(x) is the impedance function. The two first-order differential equations (1) can be expressed by a second-order differential equation as shown by:

$$\frac{{d}^{2} x}{d {t}^{2}} + \frac{d F ( x )}{d x} \frac{d x}{d t} + g ( x ) = 0$$

$$or$$

$$\frac{{d}^{2} x}{d {t}^{2}} + f ( x ) \frac{d x}{d t} + g ( x ) = 0$$

$$where$$

$$f ( x ) = \frac{d F ( x )}{d x}$$

The

$$\frac{d F ( x )}{d x}$$

in

$$\frac{d x}{d t}$$

term is the clamping term. According to the Liénard stabilized system theory, for any stabilized periodical system,

$$\frac{d F ( x )}{d x} > 0 and \frac{d F ( x )}{d x} < 0$$

hold simultaneously and the two must pass

$$\frac{d F ( x )}{d x} = 0 ,$$

where

$$\frac{d F ( x )}{d x} > 0$$

is defined as positive differential resistor or PDR in short,

$$\frac{d F ( x )}{d x} < 0$$

is defined as negative differential resistor or NDR in short, and

$$\frac{d F ( x )}{d x} = 0$$

is defined as zero differential resistor or ZDR in short.

It's obvious that a PDR, a ZDR, and a NDR electrically connected in series can satisfy

$$\frac{d F ( x )}{d x} > 0$$

$$\frac{d F ( x )}{d x} = 0 and \frac{d F ( x )}{d x} < 0$$

simultaneously and a PDR device, a ZDR and a NDR device electrically connected in series is a damper.

The PDR and the NDR are not limited to any particular PDR and NDR, for example, an embodiment, a PDR and a NDR can respectively be a positive temperature coefficient (or PTC in short) and negative temperature coefficient (or NTC in short). According to the chain-rule,

$$\frac{d F ( x )}{d x} = \frac{d F ( x )}{d x} \frac{d T}{d x}$$

where T is temperature and, assuming the state x is current,

$$\frac{d T}{d x}$$

can DC interpreted as a change in current leads to a change in temperature, and the change in temperature leads to a change in resistance as described by

$$\frac{d F ( x )}{d x} .$$

This explains a PTC and NTC can respectively be a PDR and a NDR.

More detailed about the prior-art damper can be referred to our previous invention “a capacitor” USA early publication no. US2010-0277392A1 for reference.

According to the above prior-art discussion, at least a PDR, at least a ZDR, and at least a NDR simultaneously exist in a same circuit, which can more completely describe the dynamic behavior of the circuit. A ZDR (or zero differential resistor) means a resistor having constant resistance not zero resistance. The ZDR can be viewed as a threshold or tunable term of a damper to limit current flowing through it, for example, the bigger resistance of a ZDR is the smaller current flows through a damper having the ZDR. A damper in a more general form can be viewed to have a tunable term as the ZDR and variable terms as the PDR and NDR.

The prior-art variable resistor and variable capacitor have drawbacks in the variation in bandwidth.

Both PDR and NDR of the inventive resistor can respectively have steep slopes but the resistance of PDR is usually a lot bigger than that of NDR, in the case, NDR is unable to stop the resistance of PDR from keeping going up possibly all the way to a saturation condition. Once PDR into saturation, most electrical power flowing through the inventive resistor will be converted into heat rather than in the form of oscillation and the accumulated heat is potentially harmful to the parts in the circuit.

In some applications, ac and dc of an electrical power are needed to be decoupled and then separately processed. Also, ac noise such as Lenz current produced by the switchings of a transistor can cause the transistor and the circuit having the transistor to malfunction, for example, the transistor is not precisely turned on or off as controlled. The malfunction of a transistor, such as a power transistor, can bring to a serious disaster, for example, a power transistor to control a moving vehicle or elevator. A transistor can more function normally if the unwanted ac noise such as Lenz current can be decoupled out of the terminals of the transistor. Obviously, a sensitive ac/dc decoupler with broad bandwidth is always a goal to pursue.

180° shift is commonly seen in any circuit, for example, assuming an action is applied to a circuit and a reaction to the action differs 180° in phase, for another example, on and off of a transistor and output and input of a transistor differs 180° in phase. FIG. 14 has shown a prior-art 180° phase-shifter having three RC circuits with each RC circuit shifting 60 degrees but the prior-art 180° phase-shifter is known to have drawbacks in narrow bandwidth, lower frequency and handling a signal type of electrical power.

Y and Delta (or Δ) transformers or generators are main devices in electrical power system. Both Y and Δ transformers are respectively known a type of three-phase electric power transformer design respectively conventionally called to have a R, S, and T terminals.

A smart grid is a modernized electrical grid that uses information and communications technology to gather and act on information, such as information about both the behaviors of suppliers and consumers, in an automated fashion to improve the efficiency, reliability, economics, and sustainability of the production and distribution of electricity. To gather the information about the behaviors of suppliers and consumers using Y and Delta transformers or generators needs precisional phase voltage measurement of phase voltages. Inaccurate measurement certainly brings false information about the behaviors of suppliers and consumers. Transforming the prior-art electrical power system into the smart grid has problems: (1) for Y transformer, converting the prior-art line voltage measurement into phase voltage is not accurate, and (2) transforming the prior-art electrical power system into the smart grid for both Y and Δ transformers, there is no reference for the simultaneous measurements of the three ac-based phase voltages for both Y and Δ transformers.

Assuming multiple dc electrical inputs with different voltages inputted into a coil of an inductor, only an electrical input with the highest voltage injects into the coil. Aiming to solve the problem, an inventive multiple-energy-source injector capable of modulating multiple electrical inputs with different voltages into an electrical power is revealed in the present invention. An inventive active inductance control circuit for actively controlling the inductance of an inductor is revealed in the present invention.

Switching circuit such as voltage boost circuit is a basic circuit seen in many applications. A typical switching circuit is simply introduced in FIG. 21, the switching circuit is formed by an electrical power source 120, an inductor 124 having a conductive coil 1241 and a first transistor 125 usually came with a parasitic diode in parallel to the first transistor 125 electrically connected in series with each other and an output is taken between the inductor 124 and the first transistor 125 after a diode 146. To increase the performance of the switching circuit is still a challenge.

The prior-art blocking oscillator having similar structure with the switching circuit is introduced in FIG. 23. FIG. 23 has shown a type of a prior-art blocking oscillator in a well-known form. The prior-art blocking oscillator is simply introduced first by using FIG. 23 based on the switching circuit of FIG. 21. FIG. 23 has shown a first coil 1241 and a second coil 123 winding around a same magnetic core 1234. The magnetic fluxes in the magnetic core 1234 respectively produced by current flowing through the first coil 1241 and the second coil 123 are in same direction or magnetically in phase to form a magnetic flux positive feedback as an excitation to the oscillator. A second resistor 122 is the resistance of the first coil 1241. The electrical power source 120, the inductor formed with the first coil 1241 and a first transistor 125 electrically connected in series with each other is the switching circuit of FIG. 21. The charge and the discharge of a capacitor 126 switches the first transistor 125 so that the first transistor 125 can be viewed as a self-excitation switch and the blocking oscillator has featured to be a self-excitation oscillator. It's well known the prior-art blocking oscillator has been long time suffering for bad control of into and out of oscillation mode, for example, sometimes it's very difficult to make the blocking oscillator into and out of oscillation mode as controlled.

Aiming to solve the drawbacks of prior-art variable resistor and capacitor, an inventive variable resistor and an inventive variable capacitor respectively with wide bandwidth are respectively revealed in the present invention.

An inventive resistor assembly free of PDR saturation based on the inventive variable resistor is revealed in the present invention. And, an inventive capacitor assembly free of PDR saturation based on the inventive variable resistor is also revealed in the present invention.

An inventive n-stage RC network based on the inventive variable resistor, the inventive resistor assembly, the inventive variable capacitor and the inventive capacitor assembly is revealed in the present invention. The inventive n-stage RC network has damping and phase shift capabilities and is capable of handling electrical power, for example, the inventive n-stage RC network can be 180° phase-shifter for n=3 or 360° phase-shifter for n=6, both are capable of handling electrical power.

The inventive n-stage RC network including the inventive 180° phase-shifter can be an ac/dc decoupler with good bandwidth and sensitivity. The inventive active inductance control circuit is realized by employing the inventive n-stage RC network including the inventive 180° phase-shifter.

The inventive 180° phase-shifter based on the inventive n-stage RC network, the inventive multiple-energy-source injector, and the inventive active inductance control circuit based on the inventive n-stage RC network including the inventive 180° phase-shifter are employed into the switching circuit to increase its performance.

The inventive 180° phase-shifter can function as an ac/dc decoupler to decouple ac and dc of an output of the switching circuit and the decoupled 180° shifted ac and dc can respectively be positively fedback into the switching circuit with the first transistor being on to increase the performance of the switching circuit. The inventive multiple-energy-source injector advantages to allow multiple electrical inputs with different voltages into the switching circuit. The inventive active inductance control circuit can actively vary the inductance of the inductor of the switching circuit to increase the performance of the switching circuit.

The advantagings of the switching circuit above can be applied to the prior-art blocking oscillator having similar structure with the switching circuit. Besides, the inventive 180° phase-shifter based on the inventive n-stage RC network can also be employed into the prior-art blocking oscillator as a positive feedback excitation signal to gain better control to the self-excitation oscillation.

The inventive n-stage RC network including the inventive 180° phase-shifter can be used to establish a reference for both Y and Δ transformers so the simultaneous measurements of the three ac-based phase voltages with respect to the reference for both Y and Δ transformers can be obtained. The reference also advantages transforming the prior-art electrical power system into the smart grid without needing to break open or re-coil the Δ transformer, which can reduce the cost for the transformation.

Each of R, S and T of Y and Δ transformers can be processed by an inventive 180° phase-shifter respectively shown as R′, S′, and T′ and each of R and R′, S and S′, and T and T′can respectively be two inputs of an inventive multiple-energy-source injector to smooth the output waveforms of each multiple-energy-source injector so that the R, S and T output waveforms of Y and Δ transformers can be more continuous.

### BRIEF SUMMARY OF THE INVENTION

An inventive resistor having damping capability and variable resistances is revealed in the present invention.

An inventive capacitor having damping capability and variable capacitances is revealed in the present invention.

An inventive resistor assembly free of the saturation of PDR comprising a plurality of inventive resistors electrically connected in parallel with each other is revealed in the present invention.

An inventive capacitor assembly free of the saturation of PDR comprising a plurality of inventive capacitors electrically connected in parallel with each other is revealed in the present invention.

An inventive n-stage RC network having damping capability based on the inventive resistor, the inventive resistor assembly, the inventive capacitor and/or the inventive capacitor assembly is revealed in the present invention.

An inventive 180° phase-shift RC network having 180° phase-shift capability based on the inventive resistor, the inventive resistor assembly, the inventive capacitor and/or the inventive capacitor assembly is revealed in the present invention.

An inventive 360° phase-shift RC network having 360° phase-shift capability based on the inventive resistor, the inventive resistor assembly, the inventive capacitor and/or the inventive capacitor assembly is revealed in the present invention.

An inventive multiple-energy-source injector for modulating multiple electrical inputs with different voltages into an output with a single voltage is revealed in the present invention.

An inventive ac/dc decoupler based on the inventive n-stage RC network is revealed in the present invention.

An inventive ac/dc decoupler based on the inventive 180° phase-shift RC network is revealed in the present invention.

An inventive active inductance control circuit based on the inventive n-stage RC network is revealed in the present invention.

An inventive active inductance control circuit based on the inventive 180° phase-shift RC network is revealed in the present invention.

The inventive 180° phase-shift RC network, the inventive multiple-energy-source injector and the inventive active inductance control circuit employed with a switching circuit for increasing the performance of the switching circuit is revealed in the present invention.

The inventive 180° phase-shift RC network, the inventive multiple-energy-source injector and the active inductance control circuit employed with a blocking oscillator circuit for increasing the performance of the blocking oscillator is revealed in the present invention.

The inventive 180° phase-shift RC network employed with a blocking oscillator forms a positive feedback excitation signal to increase its controllability into and out of self-excitation oscillation mode is revealed in the present invention.

The inventive n-stage RC network employed with a transistor for decoupling ac such as Lenz current presented at terminals of the transistor is revealed in the present invention.

The inventive 180° phase-shift RC network employed with a transistor for decoupling ac such as Lenz current presented at terminals of the transistor is revealed in the present invention.

The inventive n-stage phase-shift RC networks employed with a Y transformer or generator to establish a reference for the Y transformer or generator is revealed in the present invention.

The inventive n-stage RC networks employed with a Δ transformer or generator to establish a reference for the Δ transformer or generator is revealed in the present invention.

The inventive 180° phase-shift RC networks employed with a Y transformer or generator to establish a reference for the Y transformer or generator is revealed in the present invention.

The inventive 180° phase-shift RC networks employed with a Δ transformer or generator to establish a reference for the Δ transformer or generator is revealed in the present invention.

The inventive 180° phase-shift RC network and the inventive multiple-energy-source injector employed with a Y transformer or generator to smooth its output waveform is revealed in the present invention.

The inventive 180° phase-shift RC network and the inventive multiple-energy-source injector employed with a Δ transformer or generator to smooth its output waveform is revealed in the present invention.

### BRIEF DESCRIPTION OF THE SEVERAL VIEWS OF THE DRAWINGS

FIG. 1(a) has shown an embodiment of an inventive resistor having damping capability and variable resistances comprising m PDRs having different slopes from each other, n ZDRs having different resistances from each other with at least a ZDR having a non-zero resistance, and p NDRs having different slopes from each other electrically connected in series with each other;

FIG. 1(b) has shown the inventive resistor of FIG. 2(d) in multilayer structure or a multilayer resistor based on the inventive resistor of FIG. 2(d);

FIG. 2(a) is the inventive resistor of FIG. 1(a) with m=n=p=1 and a ZDR seated between a PDR and a NDR;

FIG. 2(b) is the inventive resistor of FIG. 1(a) with m=p=1 and all ZDRs seated between a PDR and a NDR;

FIG. 2(c) is the inventive resistor of FIG. 1(a) with all the PDRs grouped together forming a PDR zone, all the NDRs grouped together forming a NDR zone, and all the ZDRs grouped together forming a ZDR zone seated between the PDR zone and the NDR zone;

FIG. 2(d) is the inventive resistor of FIG. 1(a) with n=1 and all the PDRs grouped together forming a PDR zone, all the NDRs grouped together forming a NDR zone, and a ZDR seated between the PDR zone and the NDR zone;

FIG. 3 has shown an embodiment of a multilayer device;

FIG. 4(a) has shown the inventive resistor of FIG. 2(a) in multilayer structure or a multilayer resistor based on the inventive resistor of FIG. 2(a);

FIG. 4(b) has shown the inventive resistor of FIG. 2(b) in multilayer structure or a multilayer resistor based on the inventive resistor of FIG. 2(b);

FIG. 5 has shown the inventive resistor of FIG. 2(c) in multilayer structure or a multilayer resistor based on the inventive resistor of FIG. 2(c);

FIG. 6(a) is the inventive resistor of FIG. 2(a) having a ZDR protection circuit electrically connected in parallel to the ZDR and the NDR;

FIG. 6(b) is the inventive resistor of FIG. 2(b) having a ZDR protection circuit electrically connected in parallel to all the ZDRs and the NDR;

FIG. 6(c) is the inventive resistor of FIG. 2(c) having a ZDR protection circuit electrically connected in parallel to all the ZDRs and all the NDRs;

FIG. 6(d) is the inventive resistor of FIG. 2(d) having a ZDR protection circuit electrically connected in parallel to the ZDR and all the NDRs;

FIG. 7 is the multilayer resistor of FIG. 4(b) having a ZDR protection circuit electrically connected in parallel to all the ZDR layers and the NDR layer;

FIG. 8 is the multilayer resistor of FIG. 5 having a ZDR protection circuit electrically connected in parallel to all the ZDR layers and all the NDR layers;

FIG. 9 is the multilayer resistor of FIG. 1(b) having a ZDR protection circuit electrically connected in parallel to the ZDR layer and all the NDR layers;

FIG. 10(a) is an embodiment of an inventive resistor assembly based on the inventive resistors in the present invention;

FIG. 10(b) is an embodiment of an inventive capacitor assembly based on the inventive capacitors in the present invention;

FIG. 11 is an embodiment of the inventive resistor assembly of FIG. 10(a) or an embodiment of the inventive capacitor assembly of FIG. 10(b);

FIG. 12 is FIG. 11 with a first terminal and a second terminal;

FIG. 13 is an embodiment of the inventive resistor assembly of FIG. 10(a) or an embodiment of the inventive capacitor assembly of FIG. 10(b);

FIG. 14 has shown a prior-art 180° phase-shift RC network;

FIG. 15(a) has shown an inventive n-stage RC network;

FIG. 15(b) is a simple expression of the inventive n-stage RC network of FIG. 15(a);

FIG. 16 has shown an embodiment of the inventive n-stage RC network of FIG. 15(a);

FIG. 17 has shown an embodiment of the inventive n-stage RC network of FIG. 15(a);

FIG. 18 has shown an embodiment of the inventive n-stage RC network of FIG. 15(a);

FIG. 19 has shown an embodiment of the inventive n-stage RC network of FIG. 15(a);

FIG. 20 has shown an embodiment of an ac/dc decoupler based on the inventive n-stage RC network of FIG. 15(a);

FIG. 21 has shown an embodiment by employing the inventive 3-stage RC network, the inventive multiple-energy-source injector and an inventive active inductance control circuit into a prior-art switching circuit to increase the performance of the switching circuit;

FIG. 22 has shown an embodiment of an ac/dc coupler based on the inventive n-stage RC network or the inventive 180° phase-shift RC network to decouple ac from two terminals of a transistor;

FIG. 23 has introduced a prior-art blocking oscillator;

FIG. 24 has shown an embodiment by employing the inventive 3-stage RC network, the inventive multiple-energy-source injector and the inventive active inductance control circuit into a prior-art blocking oscillator to increase the performance of the blocking oscillator;

FIG. 25 has shown an embodiment of a Δ transformer or generator employing the inventive n-stage RC network to establish a reference for the Δ transformer or generator;

FIG. 26 has shown an embodiment of a Δ transformer or generator employing the inventive n-stage RC network to establish a reference for the Δ transformer or generator;

FIG. 27 has shown an embodiment of a Y transformer or generator employing the inventive n-stage RC network to establish a reference for the Y transformer or generator;

FIG. 28 has shown an embodiment of a Y transformer or generator employing the inventive n-stage RC network to establish a reference for the Y transformer or generator;

FIG. 29(a) has shown an embodiment of an ac/dc coupler based on the inventive n-stage RC network or the inventive 180° phase-shift RC network to decouple ac from two terminals of a transistor;

FIG. 29(b) has shown embodiment of an inventive active inductance control circuit based on the embodiment of FIG. 29(a);

FIG. 30 has shown each of the R, S and T terminals respectively of Δ and Y transformers or generators and each of the R, S and T terminals respectively of Δ and Y transformers or generators after the inventive 180° phase-shift RC network can be two inputs of the vienna rectifier to smooth its power waveform;

FIG. 31(a) has shown an embodiment of four PDRs having a same initial setting that includes a same initial resistance R₁ and a same initial slope;

FIG. 31(b) has shown an embodiment of four NDRs having a same initial setting that includes a same initial resistance R₂ and a same initial slope;

FIG. 31(c) has shown an embodiment of a plurality of ZDRs having different resistances from each other;

FIG. 32 is the multilayer resistor of FIG. 4(a) having a ZDR protection circuit electrically connected in parallel to the ZDR layer and the NDR layer;

FIG. 33 has shown couples of embodiments of inventive multiple-energy-source injectors;

FIG. 34 has shown an embodiment of the multiple-energy-source injector employed in the Δ transformer of FIG. 26; and

FIG. 35 has shown an embodiment of an ac/dc coupler based on the inventive n-stage RC network or the inventive 180° phase-shift RC network to decouple ac from two terminals of a transistor.

### DETAILED DESCRIPTION OF THE INVENTION

According to the above discussion, a positive differential resistor (or PDR in short), a zero differential resistor (or ZDR in short), and a negative differential resistor (or NDR in short) simultaneously exist in a same circuit and the above discussion has also revealed at least a PDR, at least a NDR and at least a ZDR electrically in series with each other is also a damper of which each ZDR can have zero or a non-zero resistance.

The PDR and the NDR hold simultaneously and the two must pass

$$\frac{d F ( x )}{d x} = 0$$

or the ZDR. If the ZDR has zero resistance implying short circuit, then the electrical power can very possibly be all dissipated at the short circuit and in some circumstances it is not expected. The ZDR having a non-zero resistance can limit current to flow through it.

The dynamic behavior of a circuit is very complicated, at least a PDR, at least a ZDR, and at least a NDR electrically connected in series with each other can better describe the dynamic behavior of the circuit. A plurality of PDRs having different slopes from each other, a plurality of NDRs having different slopes from each other, and a plurality of ZDRs having different resistances from each other with at least a ZDR having a non-zero resistance electrically connected in series with each other can more generally describe the behavior of the circuit.

An inventive resistor having damping capability and variable resistances in a general form comprises m PDRs having different slopes from each other, p NDRs having different slopes from each other, and n ZDRs having different resistances from each other with at least a ZDR having a non-zero resistance electrically connected in series with each other for m≧1, n≧1 and p≧1 and each PDR, NDR and ZDR are not limited to any particular position in the serial connection as shown in a first embodiment of FIG. 1(a).

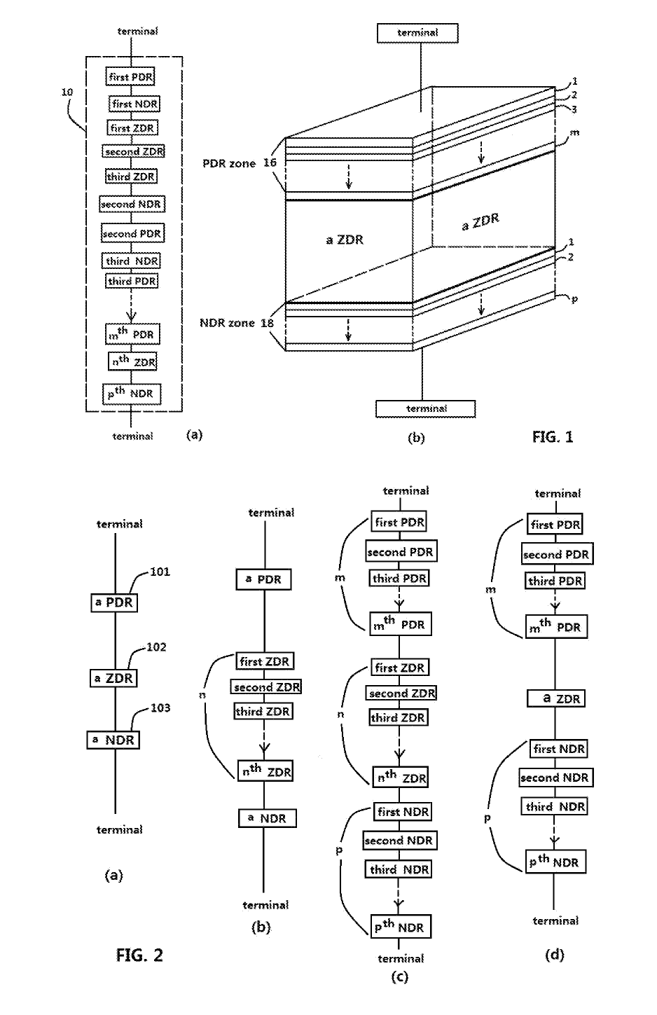

FIG. 2(a) has shown a second embodiment of the inventive resistor for m=1, n=1 and p=1 with a ZDR 102 seated between a PDR 101 and a NDR 103.

FIG. 2(b) has shown a third embodiment of the inventive resistor for m=1, p=1 and a plurality of ZDRs grouped as a ZDR zone seated between a PDR and a NDR.

FIG. 2(c) has shown a fourth embodiment of the inventive resistor having a plurality of PDRs grouped as a PDR zone, a plurality of NDRs grouped as a NDR zone, and a plurality of ZDRs grouped as a ZDR zone seated between the PDR zone and the NDR zone.

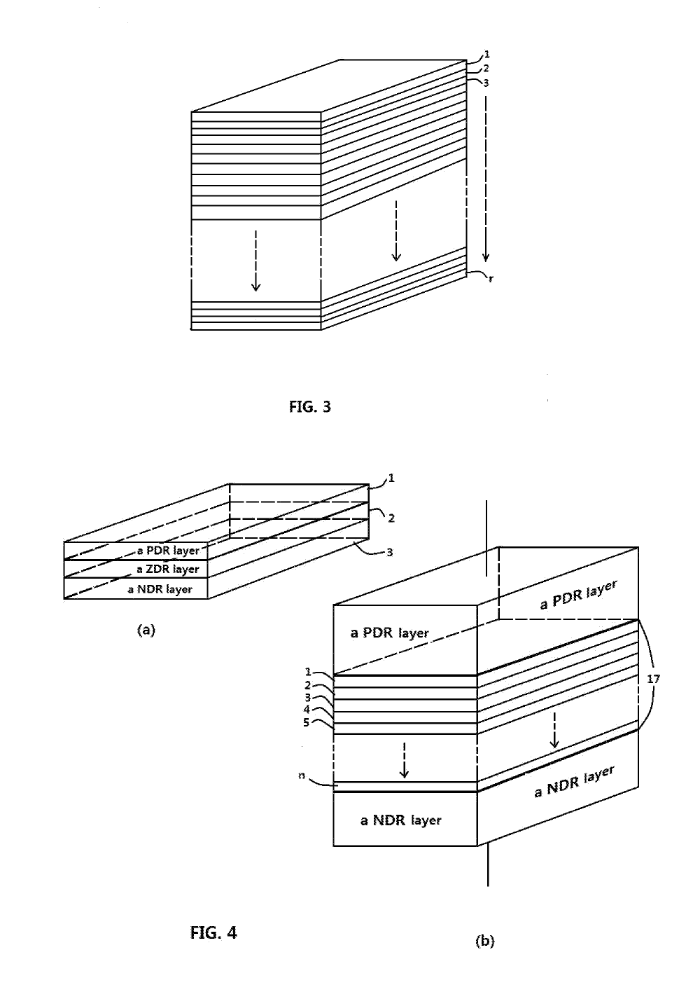

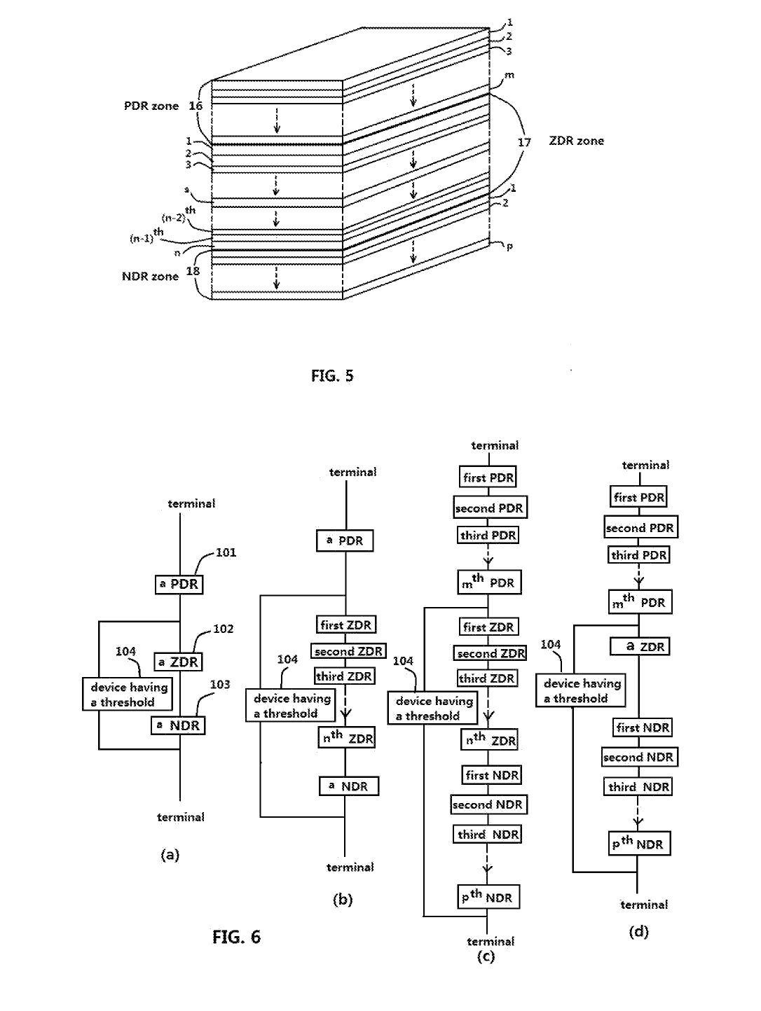

Each PDR, ZDR and NDR of the inventive resistor can be in a form of layer with one layer laying on another layer stacked up together so that the inventive resistor can be in a multilayer structure and, the inventive resistor is also called multilayer resistor in the present invention. For example, the inventive resistor of FIG. 1(a) can be in the multilayer structure shown in FIG. 3, the inventive resistor of FIG. 2(a) can be in the multilayer structure shown in FIG. 4(a), the inventive resistor of FIG. 2(b) can be in the multilayer structure shown in FIG. 4(b) and the inventive resistor of FIG. 2(c) can be in the multilayer structure shown in FIG. 5.

The ZDR of the inventive resistor is more fragile to a voltage than that of the PDR and NDR respectively having variable resistance capability so a ZDR protective circuit to protect the ZDR of the inventive resistor is needed.

Using the variable resistor of FIG. 6(a), assuming the ZDR 102 has an upper bound. A ZDR protection circuit comprises a device 104 having a threshold lower than the upper bound of the ZDR 102 electrically connected in parallel to the ZDR 102 and the NDR 103. When a voltage across the device 104 reaches its threshold the device becomes conductive then current will bypass the protected ZDR 102 and the NDR 103 and choose to go through the ZDR protection circuit having the device 104 to save the ZDR 102 at the moment. The device 104 of the ZDR protection circuit can be viewed as a NDR when it becomes conductive so the PDR 101 and the device 104 electrically connected in series is a damper capable of dissipating electrical power when the device 104 becomes conductive.

For the case of a resistor having a ZDR zone having a plurality of ZDRs, using the variable resistor of FIG. 6(c), the plurality of ZDRs can have a upper bound and the device 104 of a ZDR protection circuit having a threshold lower than the upper bound of the plurality of ZDRs is in parallel to the ZDR zone and the NDR zone as seen in FIG. 6(c).

The device having a threshold of the ZDR protection circuit is not limited to any particular device, for example, the device can be a transient-voltage-suppression diode (or called TVS in short in the present invention) or a gas discharge tube (or called GDT in short in the present invention). Both the TVS and GDT respectively have a threshold, and when a voltage across them reaching its threshold both the TVS and the GDT becomes conductive. Both the TVS and GDT can respectively be viewed as a good NDR when they become conductive. The GDT also advantages to give a visible electrical discharge as a visible warning to users.

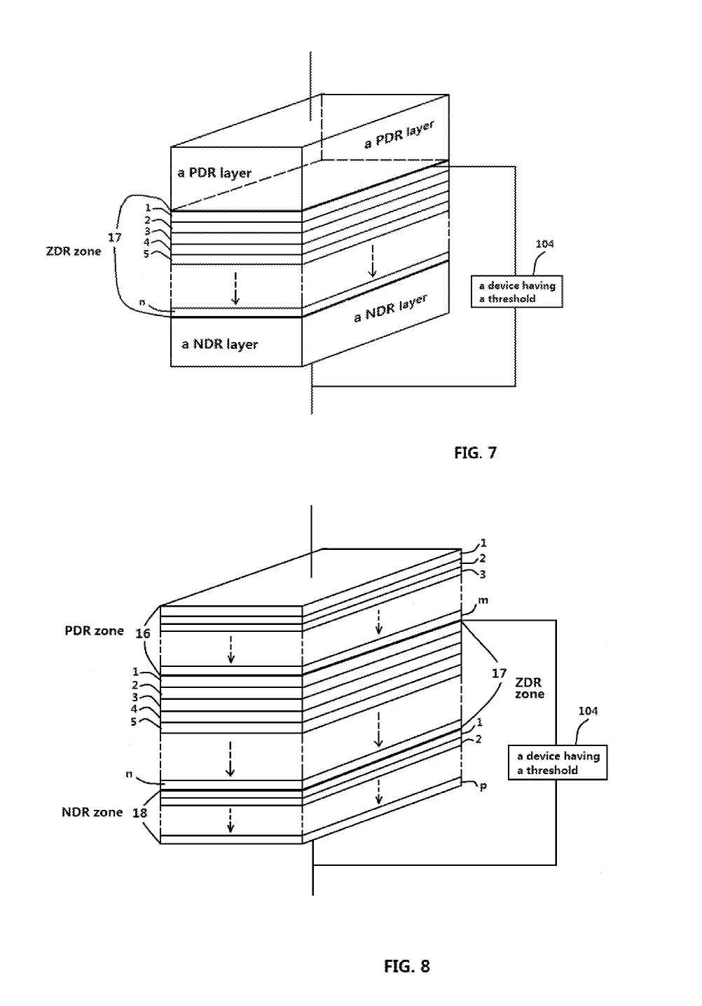

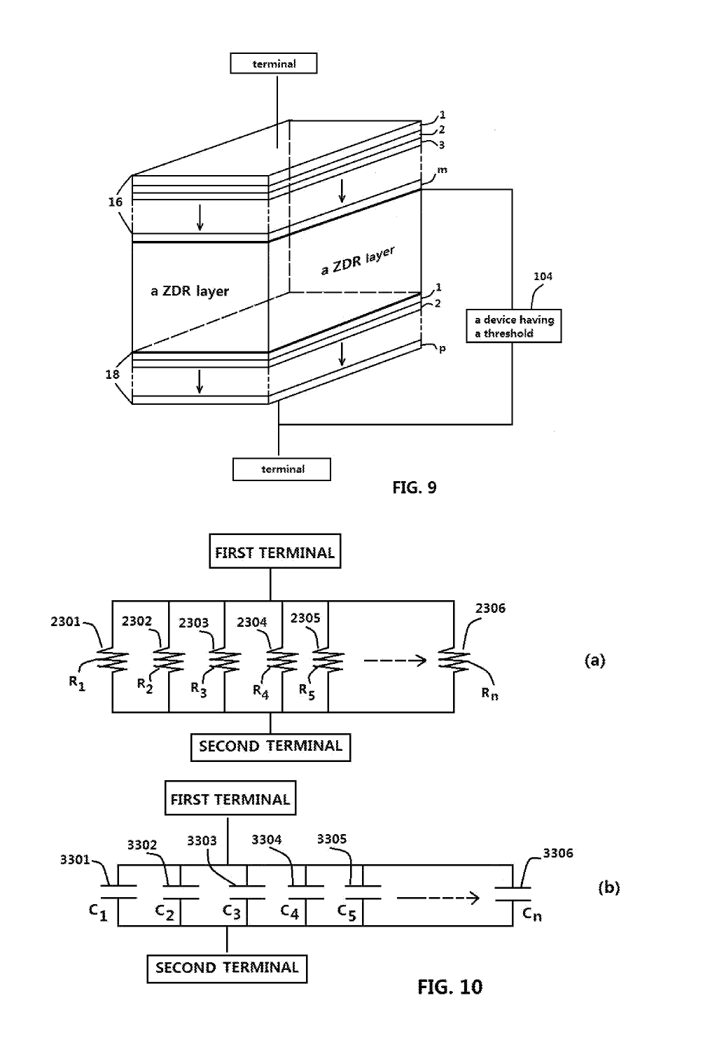

A ZDR protection circuit comprising a device having a threshold is in parallel to the ZDR or ZDRs and NDR or NDRs of the inventive resistor as shown in couple embodiments respectively of FIG. 6(a), FIG. 6(b), FIG. 6(c), FIG. 6(d), FIG. 7, FIG. 8, FIG. 9 and FIG. 32 respectively based on the embodiments of the resistors of FIG. 2(a), 2(b), 2(c), 2(d), 4(b), 1(b) 5 and FIG. 4(a).

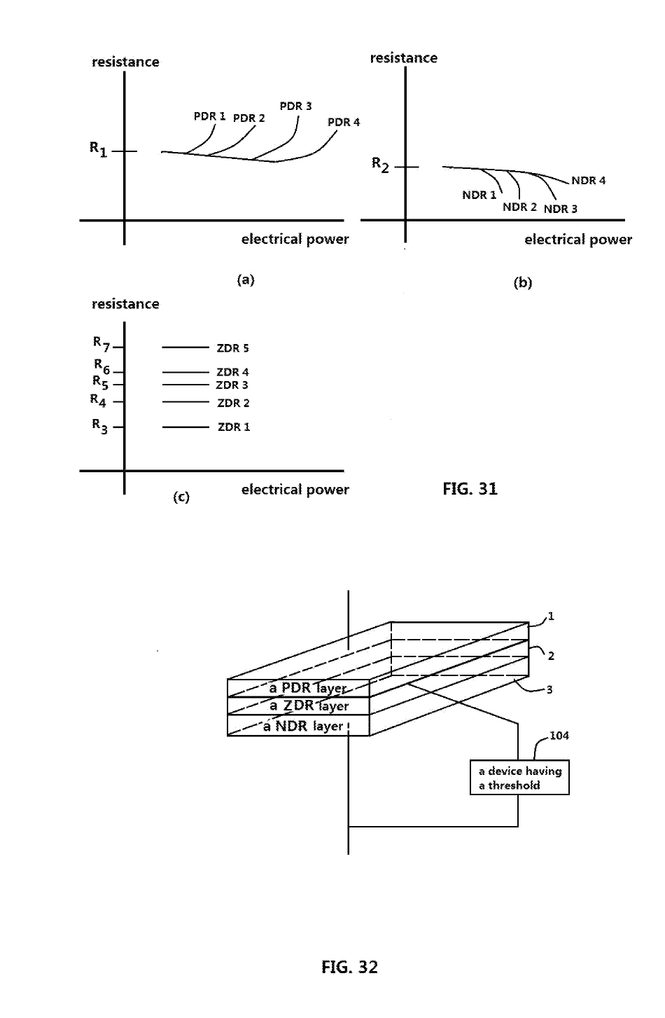

The concept of same initial setting is introduced first in FIG. 31. By using four PDRs and four NDRs, FIG. 31(a) has shown four PDRs having a same initial setting that includes a same initial resistance R₁ and a same initial slope and FIG. 31(b) has shown four NDRs having a same initial setting that includes a same initial resistance R₂ and a same initial slope. R₁ and R₂ can be same or different. FIG. 31(c) has demonstrated a plurality of ZDRs having different resistances R₃, R₄, R₅, R₆ and R₇ from each other.

A variable resistor having damping capability and variable resistances formed by a PDR, a ZDR having a non-zero resistance, and a NDR electrically connected in series with each other. The variable resistor is called as a first type variable resistor in the present invention.

An inventive variable resistor having damping capability and variable resistances comprises a PDR, a plurality of ZDRs having different resistances from each other with at least a ZDR having a non-zero resistance, and a NDR electrically connected in series with each other. The inventive variable resistor is called as a second type variable resistor in the present invention.

An inventive variable resistor having damping capability and variable resistances comprises a plurality of PDRs having different slopes from each other, a plurality of ZDRs having different resistances from each other with at least a ZDR having a non-zero resistance, and a plurality of NDRs with different slopes from each other electrically connected in series with each other. The inventive variable resistor is called as a third type variable resistor in the present invention.

An inventive variable resistor having damping capability and variable resistances comprises a plurality of PDRs having different slopes from each other, a ZDR having a non-zero resistance, and a plurality of NDRs having different slopes from each other electrically connected in series with each other. The inventive variable resistor is called as a fourth type variable resistor in the present invention.

An embodiment of the first type variable resistor, the ZDR is seated between the PDR and the NDR, the embodiment of the first type variable resistor is called a fifth type variable in the present invention.

An inventive variable resistor having damping capability and variable resistances comprises a PDR, a NDR and a ZDR zone having a plurality of ZDRs having different resistances from each other seated between the PDR and the NDR, and the PDR, the NDR and all the ZDRs are electrically connected in series with each other as shown in FIG. 2(b). The inventive variable resistor is called as a sixth type variable resistor in the present invention.

An inventive variable resistor having damping capability and variable resistances comprises a PDR zone having a plurality of PDRs having different slopes from each other, a NDR zone having a plurality of NDRs having different slopes from each other, and a ZDR zone having a plurality of ZDRs having different resistances from each other with at least a ZDR having a non-zero resistance seated between the PDR zone and the NDR zone, and all the PDRs, NDRs and ZDRs are electrically connected in series with each other as shown in FIG. 2(c). The inventive variable resistor is called as a seventh type variable resistor in the present invention.

An inventive variable resistor having damping capability and variable resistances comprises a PDR zone having a plurality of PDRs having different slopes from each other, a NDR zone having a plurality of NDRs having different slopes from each other, and a ZDR having a non-zero resistance seated between the PDR zone and the NDR zone, and all the PDRs, all the NDRs and the ZDR are electrically connected in series with each other as shown in FIG. 2(d). The inventive variable resistor is called as an eighth type variable resistor in the present invention.

A multilayer resistor having damping capability and variable resistances formed by a PDR layer, a ZDR layer having a non-zero resistance, and a NDR layer electrically connected in series with each other. For convenience, the multilayer resistor is called as a ninth type variable resistor in the present invention.

A multilayer resistor having damping capability and variable resistances comprises a PDR layer, a NDR layer and a ZDR zone having a plurality of ZDR layers having different resistances from each other with at least a ZDR layer having a non-zero resistance, and the PDR layer, the NDR layer and all the ZDR layers are electrically connected in series with each other. The multilayer resistor is called as a tenth type variable resistor in the present invention.

A multilayer resistor having damping capability and variable resistances comprises a PDR zone having a plurality of PDR layers having different slopes from each other, a NDR zone having a plurality of NDR layers having different slopes from each other, and a ZDR zone having a plurality of ZDR layers having different resistances from each other with at least a ZDR layer having a non-zero resistance, and all the PDR layers, all the NDR layers and all the ZDR layers are electrically connected in series with each other. The multilayer resistor is called as an eleventh type variable resistor in the present invention.

A multilayer resistor having damping capability and variable resistances comprises a PDR zone having a plurality of PDR layers having different slopes from each other, a NDR zone having a plurality of NDR layers having different slopes from each other, and a ZDR layer and all the PDR layers, all the NDR layers and the ZDR layer are electrically connected in series with each other. The multilayer resistor is called as a twelfth type variable resistor in the present invention.

An embodiment of the ninth type variable resistor, the ZDR layer is seated between the PDR layer and the NDR layer as shown in FIG. 4(a). The embodiment of the ninth type variable resistor is called as a thirteenth type variable resistor in the present invention.

An embodiment of the tenth type variable resistor, the ZDR zone is seated between the PDR layer and the NDR layer as shown in FIG. 4(b). The embodiment of the tenth type variable resistor is called as a fourteenth type variable resistor in the present invention.

An embodiment of the eleventh type variable resistor, the ZDR zone is seated between the PDR zone and the NDR zone as shown in FIG. 5. The embodiment of the eleventh type variable resistor is called as a fifteenth type variable resistor in the present invention.

An embodiment of the twelfth type variable resistor, the ZDR layer is seated between the PDR layer and the NDR layer as shown in FIG. 1(b). The embodiment of the twelfth type variable resistor is called as a sixteenth type variable resistor in the present invention.

The fifth type variable resistor having a ZDR protection circuit in parallel to the ZDR and the NDR as shown in FIG. 6(a) is called a seventeenth type variable resistor in the present invention.

The sixth type variable resistor having a ZDR protection circuit in parallel to the ZDR zone and the NDR as shown in FIG. 6(b) is called an eighteenth type variable resistor in the present invention.

The seventh type variable resistor having a ZDR protection circuit in parallel to the ZDR zone and the NDR zone as shown in FIG. 6(c) is called a nineteenth type variable resistor in the present invention.

The eighth type variable resistor having a ZDR protection circuit in parallel to the ZDR and the NDR zone as shown in FIG. 6(d) is called a twentieth type variable resistor in the present invention.

The thirteenth type variable resistor having a ZDR protection circuit in parallel to the ZDR layer and the NDR layer as shown in FIG. 32 is called a twenty-first type variable resistor in the present invention.

The fourteenth type variable resistor having a ZDR protection circuit in parallel to the ZDR zone and the NDR layer as shown in FIG. 7 is called a twenty-second type variable resistor in the present invention.

The fifteenth type variable resistor having a ZDR protection circuit in parallel to the ZDR zone and the NDR zone as shown in FIG. 8 is called a twenty-third type variable resistor in the present invention.

The sixteenth type variable resistor having a ZDR protection circuit in parallel to the ZDR layer and the NDR zone as shown in FIG. 9 is called a twenty-fourth type variable resistor in the present invention.

An embodiment of the third type variable resistor, all the PDRs have a same initial resistance and all the NDRs have a same initial resistance, the embodiment of the third type variable resistor is called as a twenty-fifth type variable resistor in the present invention.

An embodiment of the fourth type variable resistor, all the PDRs have a same initial resistance and all the NDRs have a same initial resistance, the embodiment of the fourth type variable resistor is called as a twenty-sixth type variable resistor in the present invention.

An embodiment of the seventh type variable resistor, all the PDRs have a same initial resistance and all the NDRs have a same initial resistance, the embodiment of the seventh type variable resistor is called as a twenty-seventh type variable resistor in the present invention.

An embodiment of the eighth type variable resistor, all the PDRs have a same initial resistance and all the NDRs have a same initial resistance, the embodiment of the eighth type variable resistor is called as a twenty-eighth type variable resistor in the present invention.

An embodiment of the eleventh type variable resistor, all the PDRs have a same initial resistance and all the NDRs have a same initial resistance, the embodiment of the eleventh type variable resistor is called as a twenty-ninth type variable resistor in the present invention.

An embodiment of the twelfth type variable resistor, all the PDRs have a same initial resistance and all the NDRs have a same initial resistance, the embodiment of the twelfth type variable resistor is called as a thirtieth type variable resistor in the present invention.

An embodiment of the fifteenth type variable resistor, all the PDRs have a same initial resistance and all the NDRs have a same initial resistance, the embodiment of the fifteenth type variable resistor is called as a thirty-first type variable resistor in the present invention.

An embodiment of the sixteenth type variable resistor, all the PDRs have a same initial resistance and all the NDRs have a same initial resistance, the embodiment of the sixteenth type variable resistor is called as a thirty-second type variable resistor in the present invention.

An embodiment of the nineteenth type variable resistor, all the PDRs have a same initial resistance and all the NDRs have a same initial resistance, the embodiment of the nineteenth type variable resistor is called as a thirty-third type variable resistor in the present invention.

An embodiment of the twentieth type variable resistor, all the PDRs have a same initial resistance and all the NDRs have a same initial resistance, the embodiment of the twentieth type variable resistor is called as a thirty-fourth type variable resistor in the present invention.

An embodiment of the twenty-third type variable resistor, all the PDRs have a same initial resistance and all the NDRs have a same initial resistance, the embodiment of the twenty-third type variable resistor is called as a thirty-fifth type variable resistor in the present invention.

An embodiment of the twenty-fourth type variable resistor, all the PDRs have a same initial resistance and all the NDRs have a same initial resistance, the embodiment of the twenty-fourth type variable resistor is called as a thirty-sixth type variable resistor in the present invention.

An embodiment of the third type variable resistor, all the PDRs have a same initial setting that includes a same initial resistance and a same initial slope and all the NDRs have a same initial setting that includes a same initial resistance and a same initial slope, the embodiment of the third type variable resistor is called as a thirty-seventh type variable resistor in the present invention.

An embodiment of the fourth type variable resistor, all the PDRs have a same initial setting that includes a same initial resistance and a same initial slope and all the NDRs have a same initial setting that includes a same initial resistance and a same initial slope, the embodiment of the fourth type variable resistor is called as a thirty-eighth type variable resistor in the present invention.

An embodiment of the seventh type variable resistor, all the PDRs have a same initial setting that includes a same initial resistance and a same initial slope and all the NDRs have a same initial setting that includes a same initial resistance and a same initial slope, the embodiment of the seventh type variable resistor is called as a thirty-ninth type variable resistor in the present invention.

An embodiment of the eighth type variable resistor, all the PDRs have a same initial setting that includes a same initial resistance and a same initial slope and all the NDRs have a same initial setting that includes a same initial resistance and a same initial slope, the embodiment of the eighth type variable resistor is called as a fortieth type variable resistor in the present invention.

An embodiment of the eleventh type variable resistor, all the PDRs have a same initial setting that includes a same initial resistance and a same initial slope and all the NDRs have a same initial setting that includes a same initial resistance and a same initial slope, the embodiment of the eleventh type variable resistor is called as a forty-first type variable resistor in the present invention.

An embodiment of the twelfth type variable resistor, all the PDRs have a same initial setting that includes a same initial resistance and a same initial slope and all the NDRs have a same initial setting that includes a same initial resistance and a same initial slope, the embodiment of the twelfth type variable resistor is called as a forty-second type variable resistor in the present invention.

An embodiment of the fifteenth type variable resistor, all the PDRs have a same initial setting that includes a same initial resistance and a same initial slope and all the NDRs have a same initial setting that includes a same initial resistance and a same initial slope, the embodiment of the fifteenth type variable resistor is called as a forty-third type variable resistor in the present invention.

An embodiment of the sixteenth type variable resistor, all the PDRs have a same initial setting that includes a same initial resistance and a same initial slope and all the NDRs have a same initial setting that includes a same initial resistance and a same initial slope, the embodiment of the sixteenth type variable resistor is called as a forty-fourth type variable resistor in the present invention.

An embodiment of the nineteenth type variable resistor, all the PDRs have a same initial setting that includes a same initial resistance and a same initial slope and all the NDRs have a same initial setting that includes a same initial resistance and a same initial slope, the embodiment of the nineteenth type variable resistor is called as a forty-fifth type variable resistor in the present invention.

An embodiment of the twentieth type variable resistor, all the PDRs have a same initial setting that includes a same initial resistance and a same initial slope and all the NDRs have a same initial setting that includes a same initial resistance and a same initial slope, the embodiment of the twentieth type variable resistor is called as a forty-sixth type variable resistor in the present invention.

An embodiment of the twenty-third type variable resistor, all the PDRs have a same initial setting that includes a same initial resistance and a same initial slope and all the NDRs have a same initial setting that includes a same initial resistance and a same initial slope, the embodiment of the twenty-third type variable resistor is called as a forty-seventh type variable resistor in the present invention.

An embodiment of the twenty-fourth type variable resistor, all the PDRs have a same initial setting that includes a same initial resistance and a same initial slope and all the NDRs have a same initial setting that includes a same initial resistance and a same initial slope, the embodiment of the twenty-fourth type variable resistor is called as a forty-eighth type variable resistor in the present invention.

Two devices respectively made of different size particles of a same material may have different characteristics and two devices respectively made of different size particles respectively of two different materials may also have different characteristics.

For example, two PDRs respectively made of different size particles of a same material can have different slopes, two PDRs respectively made of different size particles respectively of two different materials can have different slopes, two NDRs respectively made of different size particles of a same material can have different slopes, two NDRs respectively made of different size particles respectively of two different materials can have different slopes, two ZDRs respectively made of different size particles of a same material can have different resistances, and two ZDRs respectively made of different size particles respectively of two different materials can have different resistances.

An embodiment of the third type variable resistor, all the PDRs are made of different size particles from each other and all the NDRs are made of different size particles from each other, the embodiment of the third type variable resistor is called as a forty-ninth type variable resistor in the present invention.

An embodiment of the fourth type variable resistor, all the PDRs are made of different size particles from each other and all the NDRs are made of different size particles from each other, the embodiment of the fourth type variable resistor is called as a fiftieth type variable resistor in the present invention.

An embodiment of the seventh type variable resistor, all the PDRs are made of different size particles from each other and all the NDRs are made of different size particles from each other, the embodiment of the seventh type variable resistor is called as a fifty-first type variable resistor in the present invention.

An embodiment of the eighth type variable resistor, all the PDRs are made of different size particles from each other and all the NDRs are made of different size particles from each other, the embodiment of the eighth type variable resistor is called as a fifty-second type variable resistor in the present invention.

An embodiment of the eleventh type variable resistor, all the PDRs are made of different size particles from each other and all the NDRs are made of different size particles from each other, for convenience, the embodiment of the eleventh type variable resistor is called as a fifty-third type variable resistor in the present invention.

An embodiment of the twelfth type variable resistor, all the PDRs are made of different size particles from each other and all the NDRs are made of different size particles from each other, for convenience, the embodiment of the twelfth type variable resistor is called as a fifty-fourth type variable resistor in the present invention.

An embodiment of the fifteenth type variable resistor, all the PDRs are made of different size particles from each other and all the NDRs are made of different size particles from each other, for convenience, the embodiment of the fifteenth type variable resistor is called as a fifty-fifth type variable resistor in the present invention.

An embodiment of the sixteenth type variable resistor, all the PDRs are made of different size particles from each other and all the NDRs are made of different size particles from each other, for convenience, the embodiment of the sixteenth type variable resistor is called as a fifty-sixth type variable resistor in the present invention.

An embodiment of the nineteenth type variable resistor, all the PDRs are made of different size particles from each other and all the NDRs are made of different size particles from each other, the embodiment of the nineteenth type variable resistor is called as a fifty-seventh type variable resistor in the present invention.

An embodiment of the twentieth type variable resistor, all the PDRs are made of different size particles from each other and all the NDRs are made of different size particles from each other, the embodiment of the twentieth type variable resistor is called as a fifty-eighth type variable resistor in the present invention.

An embodiment of the twenty-third type variable resistor, all the PDRs are made of different size particles from each other and all the NDRs are made of different size particles from each other, the embodiment of the twenty-third type variable resistor is called as a fifty-ninth type variable resistor in the present invention.

An embodiment of the twenty-fourth type variable resistor, all the PDRs are made of different size particles from each other and all the NDRs are made of different size particles from each other, the embodiment of the twenty-fourth type variable resistor is called as a sixtieth type variable resistor in the present invention.

Both PDR and NDR of the inventive resistor can respectively have steep slopes but the resistance of PDR is usually a lot bigger than that of NDR, in the case, NDR is unable to stop the resistance of PDR from keeping going up possibly all the way to a saturation condition. Once PDR into saturation, most electrical power flowing through the resistor will be converted into heat rather than in the form of oscillation and the accumulated heat is potentially harmful to it.

An inventive resistor assembly comprising a plurality of the inventive variable resistors electrically connected in parallel with each other can solve the problem. FIG. 10(a) has shown an inventive resistor assembly having damping capability and variable resistances comprising n resistors R₁ 2301, R₂ 2302, R₃ 2303, R₄ 2304, R₅ 2305 and up to Rₙ 2306 for n≧2 electrically connected in parallel with each other and each resistor of the n resistors can be any one of the first, second, third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, twenty-second, twenty-third, twenty-fourth, twenty-fifth, twenty-sixth, twenty-seventh, twenty-eighth, twenty-ninth, thirtieth, thirty-first, thirty-second, thirty-third, thirty-fourth, thirty-fifth, thirty-sixth, thirty-seventh, thirty-eighth, thirty-ninth, fortieth, forty-first, forty-second, forty-third, forty-fourth, forty-fifth, forty-sixth, forty-seventh, forty-eighth, forty-ninth, fiftieth, fifty-first, fifty-second, fifty-third, fifty-fourth, fifty-fifth, fifty-sixth, fifty-seventh, fifty-eighth, fifty-ninth, and sixtieth type variable resistors defined above. For convenience, the resistor assembly is called as a first type resistor assembly in the present invention.

For simplicity, each resistor of the first, second, third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, twenty-second, twenty-third, twenty-fourth, twenty-fifth, twenty-sixth, twenty-seventh, twenty-eighth, twenty-ninth, thirtieth, thirty-first, thirty-second, thirty-third, thirty-fourth, thirty-fifth, thirty-sixth, thirty-seventh, thirty-eighth, thirty-ninth, fortieth, forty-first, forty-second, forty-third, forty-fourth, forty-fifth, forty-sixth, forty-seventh, forty-eighth, forty-ninth, fiftieth, fifty-first, fifty-second, fifty-third, fifty-fourth, fifty-fifth, fifty-sixth, fifty-seventh, fifty-eighth, fifty-ninth, and sixtieth type variable resistors in sequence can be simply expressed as each resistor of the first type variable resistor the sixtieth type variable resistor in the present invention.

Current will first choose to flow through a resistor with the smallest resistance of the inventive first type resistor assembly, for example, a first resistor, at a transient moment causing the resistance of PDR or PDRs of the first resistor to grow bigger resulting in the increasing of the resistance of the first resistor. As long as the resistance of the first resistor becomes larger than that of any one resistor of the first type resistor assembly, current will choose to flow through another resistor with the smallest resistance of the first type resistor assembly, for example, a second resistor, at that transient moment causing the resistance of a PDR or PDRs of the second resistor to grow bigger resulting in the increasing of the resistance of the second resistor and the resistance of the PDR or PDRs of the first resistor to drop due to the absence of current flowing through the first resistor resulting in the drop of the resistance of the first resistor. As long as the resistance of the second resistor becomes larger than that of any one resistor of the first type resistor assembly, current will choose to flow through a resistor with the smallest resistance of the first type resistor assembly, for example, a third resistor, at that transient moment causing the resistance of a PDR or PDRs of the third resistor to grow bigger resulting in the increasing of the resistance of the third resistor and the resistance of the PDR or PDRs of the second resistor to drop due to the absence of current flowing through the second resistor resulting in the drop of the resistance of the second resistor. The process continues with current switchingly flowing through the plurality of resistors in parallel featuring any one PDR of the first type resistor assembly has less or no chance going into saturation and the produced heat can be decentralized by the n resistors.

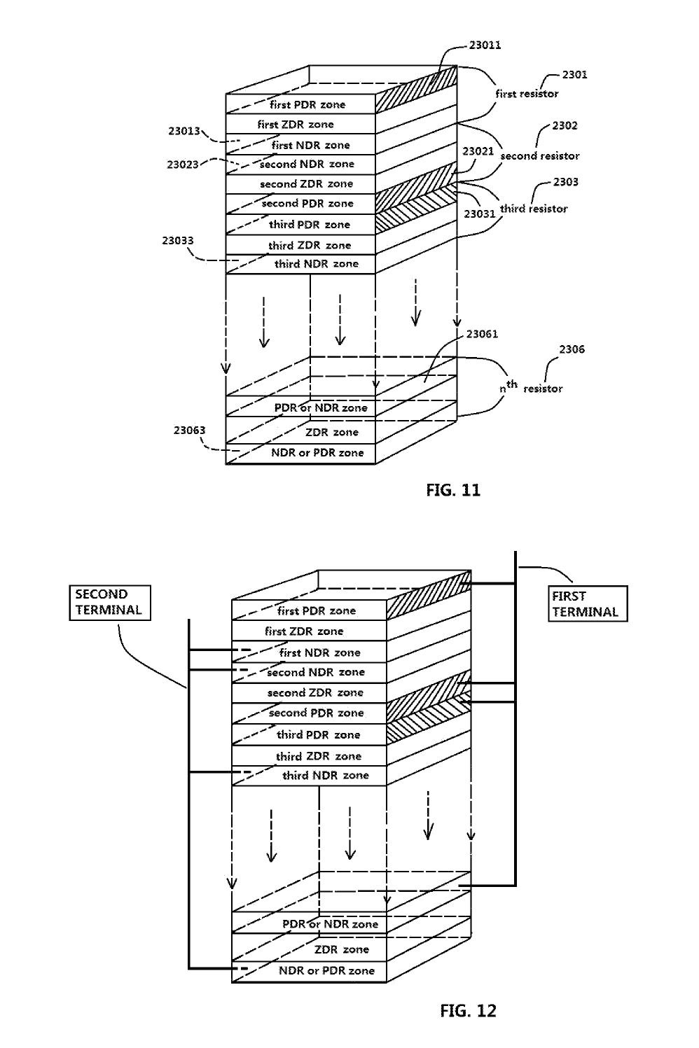

Couples of embodiments based on the inventive first type resistor assembly of FIG. 10(a) with each resistor based on FIG. 5 are shown in FIG. 11. The resistor of FIG. 5 has a PDR zone having a plurality of PDR layers having different slopes from each others, a NDR zone having a plurality of NDR layers having different slopes from each others, and a ZDR zone having a plurality of ZDR layers having different resistances from each other with at least a ZDR layer having a non-zero resistance seated between the PDR zone and the NDR zone.

With each resistor based on FIG. 5, an embodiment of the inventive first type resistor assembly of FIG. 10(a) can be formed by n resistors stacked up together by laying one resistor on another resistor with two PDR zones or two NDR zones respectively of two neighboring resistors attached together as shown in FIG. 11, in other words, a PDR zone and a NDR zone respectively of two resistors of the stack-up can not attach together without a ZDR zone seated between them.

FIG. 11 has shown a first resistor 2301 comprising a first PDR zone, a first ZDR zone and a first NDR zone, a second resistor 2302 comprising a second PDR zone, a second ZDR zone and a second NDR zone, a third resistor 2303 comprising a third PDR zone, a third ZDR zone and a third NDR zone, and so on to a n resistor 2306 stacked up together with two PDR zones or two NDR zones respectively of two neighboring resistors attached together. For example, as seen in the embodiment of FIG. 11, the second NDR zone of the second resistor 2302 is attached to the first NDR zone of the first resistor 2301 and the third PDR zone of the third resistor 2303 is attached to the second PDR zone of the second resistor 2302.

A side of each PDR layer of a PDR zone not attached to a ZDR layer or a PDR layer electrically connected together forms a terminal side of each PDR zone such as a first PDR terminal side 23011 of the first PDR zone and a second PDR terminal side 23021 of the second PDR zone shown in FIG. 11 and a side of each NDR layer of a NDR zone not attached to a ZDR layer or a NDR layer electrically connected together forms a terminal side of each NDR zone such as a first NDR terminal side 23013 of the first NDR zone and a second NDR terminal side 23023 of the second NDR zone seen in FIG. 11 and all the terminal sides respectively of the PDR zones electrically connected together form a first terminal of the inventive first type resistor assembly of FIG. 10(a) and all the terminal sides respectively of the NDR zones electrically connected together form a second terminal of the inventive first type resistor assembly of FIG. 10(a) as shown in FIG. 12.

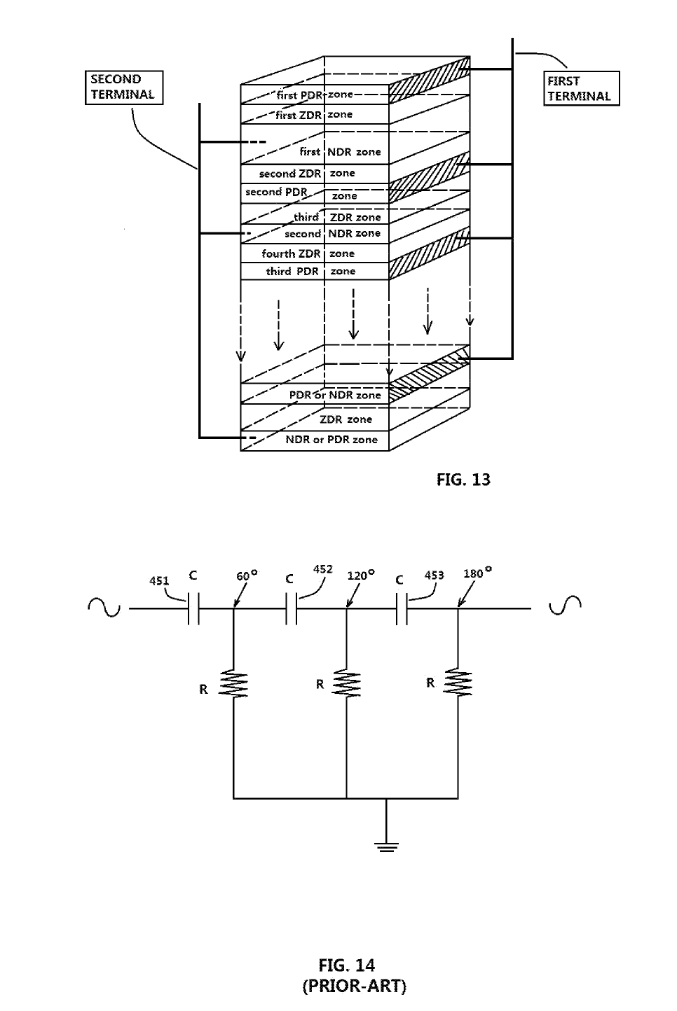

Two attached PDR zones respectively of two neighboring resistors or two attached NDR zones respectively of two neighboring resistors of FIG. 12 can be respectively viewed as a PDR zone or a NDR zone so FIG. 12 can be modified to FIG. 13, for example, as seen in FIG. 13, a first resistor 2301 formed by a first PDR zone, a first ZDR zone and a first NDR zone, a second resistor 2302 formed by a second PDR zone, a second ZDR zone and the first NDR zone, a third resistor 2303 formed by the second PDR zone, a third ZDR zone and a second NDR zone, a fourth resistor 2304 formed by a third PDR zone, a fourth ZDR zone and the second NDR zone, and so on to a n resistor 2306.

Each resistor of the first type resistor assembly shown in FIG. 5 can be the fifteenth type variable resistor, twenty-third type variable resistor, thirty-first type variable resistor, thirty-fifth type variable resistor, forty-third type variable resistor, forty-seventh type variable resistor, fifty-fifth type variable resistor or fifty-ninth type variable resistor defined earlier above.

For convenience, the embodiment of the inventive first type resistor assembly shown in FIG. 12 or FIG. 13 with each resistor being the fifteenth type variable resistor is called a second type resistor assembly in the present invention, the embodiment of the inventive first type resistor assembly shown in FIG. 12 or FIG. 13 with each resistor being the twenty-third type variable resistor is called a third type resistor assembly in the present invention, the embodiment of the inventive first type resistor assembly shown in FIG. 12 or FIG. 13 with each resistor being the thirty-first type variable resistor is called a fourth type resistor assembly in the present invention, the embodiment of the inventive first type resistor assembly shown in FIG. 12 or FIG. 13 with each resistor being the thirty-fifth type variable resistor is called a fifth type resistor assembly in the present invention, the embodiment of the inventive first type resistor assembly shown in FIG. 12 or FIG. 13 with each resistor being the forty-third type variable resistor is called a sixth type resistor assembly in the present invention, the embodiment of the inventive first type resistor assembly shown in FIG. 12 or FIG. 13 with each resistor being the forty-seventh type variable resistor is called a seventh type resistor assembly in the present invention, the embodiment of the inventive first type resistor assembly shown in FIG. 12 or FIG. 13 with each resistor being the fifty-fifth type variable resistor is called an eighth type resistor assembly in the present invention, and the embodiment of the inventive first type resistor assembly shown in FIG. 12 or FIG. 13 with each resistor being the fifty-ninth type variable resistor is called a ninth type resistor assembly in the present invention.

Assuming each resistor of each of the first^{˜}ninth type resistor assemblies has an equivalent ZDR resistance by summing up the resistances of all its ZDR layers of a ZDR zone.

An embodiment of the inventive first type resistor assembly, all the resistors of the inventive first type resistor assembly have a same equivalent ZDR resistance, for convenience, the embodiment of the inventive first type resistor assembly is called as a tenth type resistor assembly in the present invention.

An embodiment of the inventive second type resistor assembly, all the resistors of the inventive first type resistor assembly have a same equivalent ZDR resistance, for convenience, the embodiment of the inventive first type resistor assembly is called as an eleventh type resistor assembly in the present invention.

An embodiment of the inventive third type resistor assembly, all the resistors of the inventive first type resistor assembly have a same equivalent ZDR resistance, for convenience, the embodiment of the inventive first type resistor assembly is called as a twelfth type resistor assembly in the present invention.

An embodiment of the inventive fourth type resistor assembly, all the resistors of the inventive first type resistor assembly have a same equivalent ZDR resistance, for convenience, the embodiment of the inventive first type resistor assembly is called as a thirteenth type resistor assembly in the present invention.

An embodiment of the inventive fifth type resistor assembly, all the resistors of the inventive first type resistor assembly have a same equivalent ZDR resistance, for convenience, the embodiment of the inventive first type resistor assembly is called as a fourteenth type resistor assembly in the present invention.

An embodiment of the inventive sixth type resistor assembly, all the resistors of the inventive first type resistor assembly have a same equivalent ZDR resistance, for convenience, the embodiment of the inventive first type resistor assembly is called as a fifteenth type resistor assembly in the present invention.

An embodiment of the inventive seventh type resistor assembly, all the resistors of the inventive first type resistor assembly have a same equivalent ZDR resistance, for convenience, the embodiment of the inventive first type resistor assembly is called as a sixteenth type resistor assembly in the present invention.

An embodiment of the inventive eighth type resistor assembly, all the resistors of the inventive first type resistor assembly have a same equivalent ZDR resistance, for convenience, the embodiment of the inventive first type resistor assembly is called as a seventeenth type resistor assembly in the present invention.

An embodiment of the inventive ninth type resistor assembly, all the resistors of the inventive first type resistor assembly have a same equivalent ZDR resistance, for convenience, the embodiment of the inventive first type resistor assembly is called as an eighteen type resistor assembly in the present invention.

An embodiment of the inventive first type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a nineteenth type resistor assembly in the present invention.

An embodiment of the inventive second type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twentieth type resistor assembly in the present invention.

An embodiment of the inventive third type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twenty-first type resistor assembly in the present invention.

An embodiment of the inventive fourth type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twenty-second type resistor assembly in the present invention.

An embodiment of the inventive fifth type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twenty-third type resistor assembly in the present invention.

An embodiment of the inventive sixth type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twenty-fourth type resistor assembly in the present invention.

An embodiment of the inventive seventh type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twenty-fifth type resistor assembly in the present invention.

An embodiment of the inventive eighth type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twenty-sixth type resistor assembly in the present invention.

An embodiment of the inventive ninth type resistor assembly, all the PDRs of the inventive first type resistor assembly have a same initial setting that includes a same initial resistance and a same initial slope, all the NDRs of the inventive first type resistor assembly have a same initial setting that includes a same initial resistance and a same initial slope, and all the resistors of the inventive first type resistor assembly have a same equivalent ZDR resistance, for convenience, the embodiment of the inventive first type resistor assembly is called as a twenty-seventh type resistor assembly in the present invention.

Current flowing through the first type resistor assembly will be more quickly and evenly distributed among the plurality of resistors if the discrepancies in resistors among the plurality of resistors are as small as possible and heat produced by current flowing through the first type resistor assembly can be more evenly distributed among the plurality of the resistors so heat burden on each resistor will be lowered.

An embodiment of the inventive first type resistor assembly, all the resistors electrically connected in parallel with each other of the inventive first type resistor assembly are identical, for example, all the resistors electrically connected in parallel with each other of the inventive first type resistor assembly can have a same specification and can be manufactured by a same process. All the identical resistors can still be viewed to have discrepancies with each other even they are manufactured by the same process. For convenience, the embodiment of the inventive first type resistor assembly is called as a twenty-eighth type resistor assembly in the present invention. Current flowing through the twenty-eighth type resistor assembly will be more quickly and evenly distributed among the plurality of identical resistors

At least a ZDR layer of each of the thirteenth, fourteenth, fifteenth, sixteenth, thirty-first, forty-third and fifty-fifth type variable resistors has very high resistance viewed as an insulator or a dielectric under a dc voltage applied across the resistor, then each of the thirteenth, fourteenth, fifteenth, sixteenth, thirty-first, forty-third and fifty-fifth type variable resistors can be viewed as a multilayer capacitor having damping capability and variable capacitances because any resistance change causes its capacitance to change. For convenience, the multilayer capacitors respectively based on the thirteenth, fourteenth, fifteenth, sixteenth, thirty-first, forty-third and fifty-fifth type variable resistors are respectively called as a first type variable capacitor, a second type variable capacitor, a third type variable capacitor, a fourth type variable capacitor, a fifth type variable capacitor, a sixth type variable capacitor and a seventh type variable capacitor in the present invention.

At least a ZDR layer of each resistor of each of the first, second, third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, twenty-second, twenty-third, twenty-fourth, twenty-fifth, twenty-sixth, twenty-seventh and twenty-eighth type resistor assemblies has very high resistance viewed as an insulator or a dielectric under a dc voltage applied across the resistor, then each resistor of each of the first, second, third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, twenty-second, twenty-third, twenty-fourth, twenty-fifth, twenty-sixth, twenty-seventh and twenty-eighth type resistor assemblies can be viewed as a multilayer capacitor featuring damping capability and variable capacitances, and each of the first type resistor assembly the twenty-eighth type resistor assembly can be expressed by n capacitors electrically connected in parallel with each other forming a capacitor assembly as shown in FIG. 10(b). For convenience, a capacitor assembly respectively based on each of the first, second, third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, twenty-second, twenty-third, twenty-fourth, twenty-fifth, twenty-sixth, twenty-seventh and twenty-eighth type resistor assemblies are respectively called as a first, second, third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, twenty-second, twenty-third, twenty-fourth, twenty-fifth, twenty-sixth, twenty-seventh and twenty-eighth type capacitor assemblies in the present invention.

An embodiment of each of the first type capacitor assembly˜the twenty-seventh type capacitor assembly, all the capacitors of each of the first type capacitor assembly˜the twenty-seventh type capacitor assembly has an identical ZDR zone with an identical ZDR layer or identical ZDR layers as a dielectric under a dc voltage. For convenience, the embodiment of the first type capacitor assembly˜the twenty-seventh type capacitor assembly are respectively called as a twenty-ninth type capacitor assembly˜a fifth-sixth type capacitor assembly in the present invention.

Ac current will first choose to flow through a capacitor with the smallest impedance of the capacitor assembly, for example, a first capacitor, at a transient moment causing the resistance of PDR or PDRs of the first capacitor to grow bigger resulting in the increasing of the impedance of the first capacitor. As long as the impedance of the first capacitor becomes larger than that of any one capacitor of the first capacitor assembly, ac current will choose to flow through another capacitor with the smallest impedance of the capacitor assembly, for example, a second capacitor, at that transient moment causing the resistance of a PDR or PDRs of the second capacitor to grow bigger resulting in the increasing of the impedance of the second capacitor and the resistance of the PDR or PDRs of the first capacitor to drop resulting in the drop of the impedance of the first capacitor due to the absence of ac current flowing through the first capacitor. As long as the impedance of the second capacitor becomes larger than that of any one capacitor of the capacitor assembly, ac current will choose to flow through a capacitor with the smallest impedance of the capacitor assembly, for example, a third capacitor, at that transient moment causing the resistance of a PDR or PDRs of the third capacitor to grow bigger resulting in the increasing of the impedance of the third capacitor and the resistance of the PDR or PDRs of the second capacitor to drop resulting in the drop of the impedance of the second capacitor due to the absence of ac current flowing through the second capacitor. The process continues with ac current switchingly flowing through the plurality of capacitors in parallel featuring any one PDR of the capacitor assembly having less or no chance going into saturation. Any resistance change of each multilayer capacitor causes its capacitance to change and each multilayer capacitor has featured damping capability and variable capacitances.

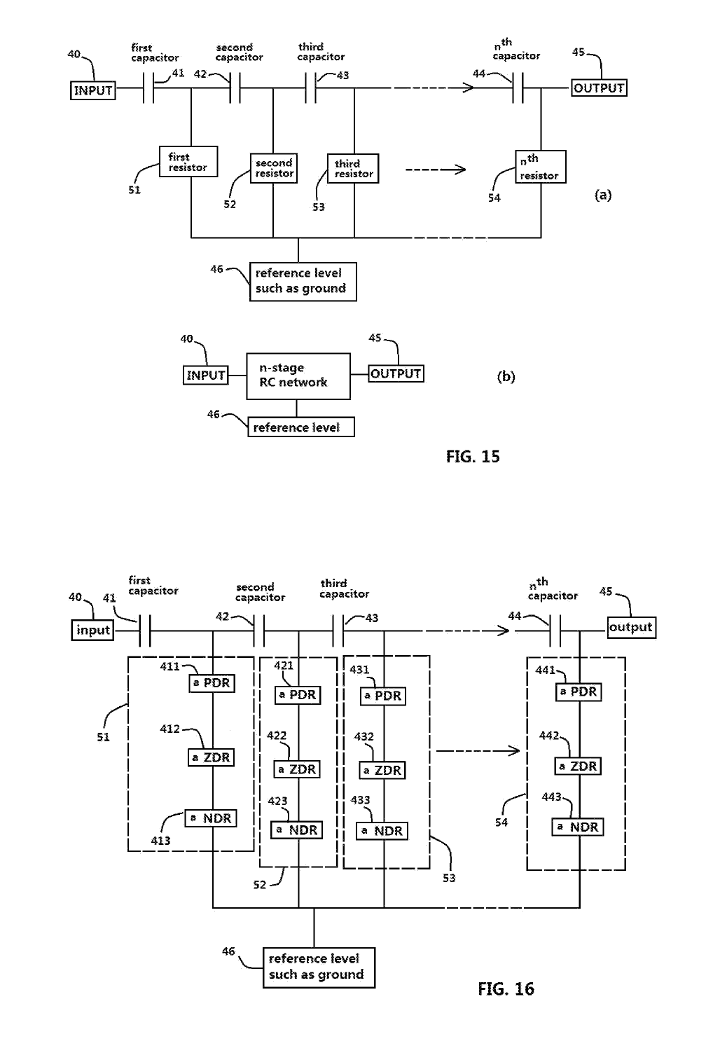

An inventive n-stage RC network comprises n RC circuits with each RC circuit having damping and phase-shift capability as shown in an embodiment of FIG. 15(a). Capacitor is known as a two-terminal device or capacitor has two terminals of which one terminal is an input terminal and the other one is an output terminal and a plurality of capacitors electrically connected in series with each other form two terminals by the serial connections of which one terminal is an input terminal of a first capacitor of the plurality of capacitors connected in series and the other one terminal is an output terminal of a last capacitor of the plurality of capacitors connected in series.

FIG. 15(a) has shown an inventive n-stage RC network comprising n RC circuits for n≧1 with each RC circuit having a capacitor having an input terminal and an output terminal and a resistor having a first terminal and a second terminal with its first terminal electrically connecting to the output terminal of the capacitor. It's obviously, the n-stage RC network has n capacitors and n resistors.

FIG. 15(a) has shown a first capacitor 41 having an input terminal for receiving an electrical input 40 of the n-stage RC network and an output terminal, a second capacitor 42 having an input terminal electrically connected with the output terminal of the first capacitor 41 and an output terminal, a third capacitor 43 having an input terminal electrically connected with the output terminal of the second capacitor 42 and an output terminal, and so on to a n^{th} capacitor 44 having an input terminal electrically connected with the output terminal of the (n−1)^{th} capacitor (not shown in FIG. 15(a)) and an output terminal as the output terminal 45 of the n-stage RC network, a first resistor 51 having a first terminal and a second terminal with the first terminal electrically connected to the output terminal of the first capacitor 41, a second resistor 52 having a first terminal and a second terminal with the first terminal electrically connected to the output terminal of the second capacitor 42, a third resistor 53 having a first terminal and a second terminal with the first terminal electrically connected to the output terminal of the third capacitor 43 and so on to a n^{th} resistor 54 having a first terminal and a second terminal with the first terminal electrically connected to the output terminal of the n^{th} capacitor. The second terminals respectively of all the resistors can be electrically connected together to forming a reference 46 of the inventive n-stage RC network. The reference 46 can be ground. The second terminals respectively of all the resistors electrically connected together can also be viewed to form a third terminal of the inventive n-stage RC network so that the n-stage RC network can also be simply expressed by FIG. 15(b) having three terminals of which a first terminal is for receiving an input, a second terminal is for outputting, and a third terminal is used as a reference.

All the resistors 51˜54 of the inventive n-stage RC network allow discrepancies in resistance from each other. All the capacitors 41˜44 of the inventive n-stage RC network allow discrepancies in capacitance from each other.

Each capacitor of the inventive n-stage RC network of FIG. 15(a) is not limited to any particular capacitor, for example, each capacitor of the inventive RC network can be any one of a prior-art capacitor, the first type capacitor˜the seventh type capacitor, and the first type capacitor assembly˜the fifty-sixth type capacitor assembly. Any two capacitors of the inventive n-stage RC network can have same or different number of PDRs, NDRs and ZDRs. Each resistor of the inventive n-stage RC network of FIG. 15(a) is not limited to any particular resistor, for example, each resistor of the inventive n-stage RC network can be any one of a prior-art resistor, the first type variable resistor˜the sixtieth type variable resistor, and the first type resistor assembly˜the twenty-eighth type resistor assembly defined above. For convenience, the inventive n-stage RC network is called as a first type n-stage RC network in the present invention.

A first embodiment of the first type n-stage RC network, all the PDRs of the first type n-stage RC network have a same initial setting that includes a same initial resistance and a same initial slope and all the NDRs of the first type n-stage RC network have a same initial setting that includes a same initial resistance and a same initial slope. For convenience, the first embodiment of the first type n-stage RC network is called as a second type n-stage RC network in the present invention.

A second embodiment of the first type n-stage RC network, all the PDRs of the first type n-stage RC network have a same initial setting that includes a same initial resistance and a same initial slope and all the NDRs of the first type n-stage RC network have a same initial setting that includes a same initial resistance and a same initial slope and all the resistors of the first type n-stage RC network have a same equivalent ZDR resistance. For convenience, the second embodiment of the first type n-stage RC network is called as a third type n-stage RC network in the present invention.

A third embodiment of the first type n-stage RC network, all the resistor assemblies of the first type n-stage RC network are identical. All the identical resistor assemblies can still be viewed to have discrepancies with each other even they are manufactured by the same process. For convenience, the third embodiment of the first type n-stage RC network is called as a fourth type n-stage RC network in the present invention.

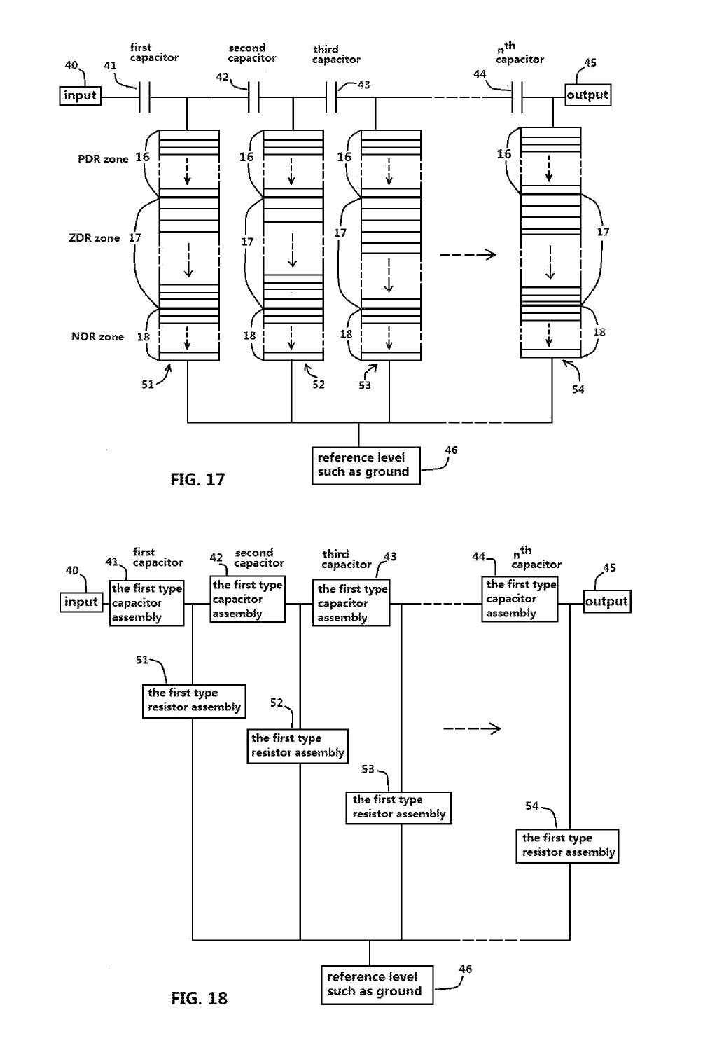

A fourth embodiment of the inventive n-stage RC network of FIG. 15(a), the first terminal of each resistor is a terminal of a PDR or a PDR zone of the resistor to let the PDR or PDRs first respond to the electrical input, for example, an embodiment of the inventive n-stage RC network of FIG. 15(a) by assuming each resistor of the inventive n-stage RC network of FIG. 15(a) to be the fifth type variable resistor of FIG. 2(a) is shown in FIG. 16, which has shown the first terminal of the first resistor 51 is a terminal of the PDR 411, the first terminal of the second resistor 52 is a terminal of the PDR 421 and the first terminal of the third resistor 53 is a terminal of the PDR 431. For another example, an embodiment of the inventive n-stage RC network of FIG. 15(a) by assuming each resistor of the inventive n-stage RC network of FIG. 15(a) to be the fifteenth type variable resistor of FIG. 5 is shown in FIG. 17, which has shown the first terminal of the first resistor 51 is a terminal of the PDR zone 16 of the first resistor 51, the first terminal of the second resistor 52 is a terminal of the PDR zone 16 of the second resistor 52 and the first terminal of the third resistor 53 is a terminal of the PDR zone of the third resistor 53.

The fourth embodiment based on the first type n-stage RC network is called as a fifth type n-stage RC network in the present invention, the fourth embodiment based on the second type n-stage RC network is called as a sixth type n-stage RC network in the present invention, the fourth embodiment based on the third type n-stage RC network is called as a seventh type n-stage RC network in the present invention and the fourth embodiment based on the fourth type n-stage RC network is called as an eighth type n-stage RC network in the present invention.

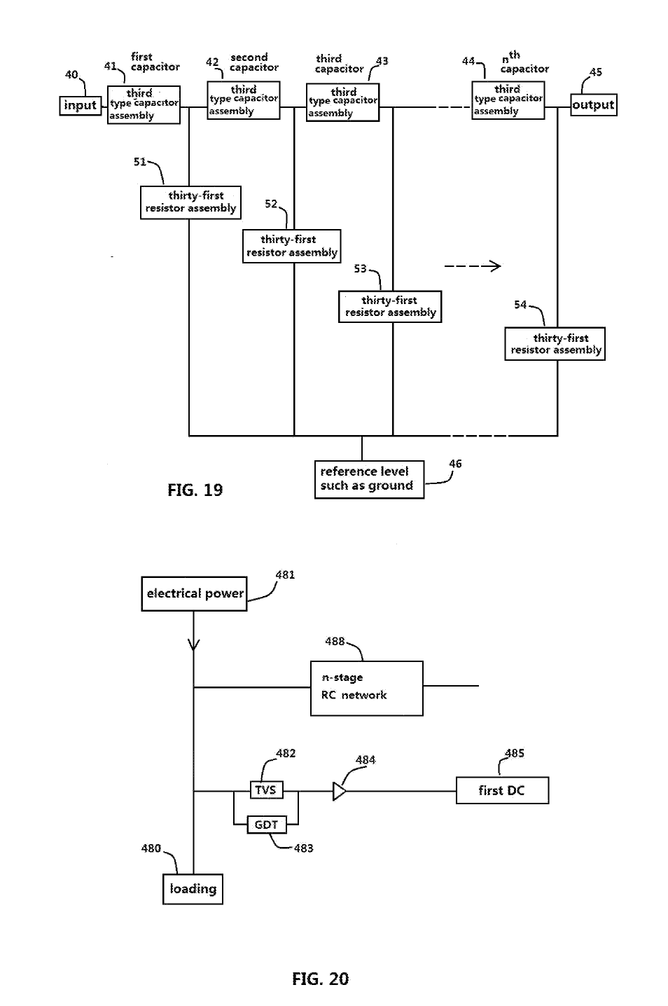

FIG. 18 has shown an embodiment of the inventive n-stage RC network with each resistor being the first type resistor assembly and each capacitor being the first type capacitor assembly and FIG. 19 has shown an embodiment of the inventive eighth type n-stage RC network with each resistor being the thirty-first type resistor assembly and each capacitor being the third type capacitor assembly.

Once an electrical power flowing into the inventive n-stage RC network the electrical power gets attenuated by the damping function of each RC circuit. The ZDR of each RC circuit can be viewed as a current limiter. If a resistor of a RC circuit of the inventive n-stage RC network has PDR and NDR but no ZDR, then the electrical power flowing into the n-stage RC network will be more likely to be all dissipated at the resistor and the output of the RC network becomes unpredictable and uncontrollable.

With the ZDR of each RC circuit, an electrical power into the inventive n-stage RC network has more chances to be distributed among the multiple RC circuits against all being dissipated at a resistor without ZDR and the resistance of ZDR of each resistor relates to the output of the n-stage RC network. By properly choosing the resistance of each ZDR, a desirable percentage output of the inventive n-stage RC network can be obtained, in other words, the ZDR can be viewed as a tuning or controlling term of the output of the inventive n-stage RC network.

For example, the resistance of the ZDR or the ZDRs of each resistor is chosen to be high to limit current in an expected amount and the PDR or PDRs can further grow bigger to further limit current so that the current flowing through each resistor of n-stage RC network can be as small as ignored and a considerate output can be obtained.

The inventive n-stage RC network has n closed RC circuits with each having damping capability to electrically dissipate electrical power so the inventive n-stage RC network features to allow its output terminal to be floated or opened because the electrical power into the n-stage RC network can still be dissipated by the n closed RC circuits even the output terminal of the n-stage RC network is floated or opened. The inventive n-stage RC network also advantages the dissipated power and produced heat can be decentralized by the n RC circuits so the heat burden on each RC circuit will be reduced. The inventive n-stage RC network also features to produce a third terminal as a reference level, in other words, the inventive RC network can be viewed to have three terminals as an input terminal, an output terminal and a reference level terminal.

FIG. 14 has introduced a well known prior-art 180° phase-shift RC network formed by three RC circuits having three capacitors respectively of the three RC circuits having a same capacitance and three resistors respectively of the three RC circuits having a same resistance. The prior-art 180° phase-shift RC network of FIG. 14 has three RC circuits or is a 3-stage RC circuit with each RC circuit shifting 60 degrees.

Each resistor or resistor assembly of the inventive n-stage RC network has variable resistance capability so all the resistors or resistor assemblies can dynamically adjust to finalize a same resistance at a moment. It will more quickly reach to a same resistance for all the resistors or resistor assemblies if the discrepancies in resistance among the resistors are smaller and it may take longer time for all the resistors to reach to a same resistance if the discrepancies in resistance among the resistors are larger. An inventive 180° phase-shift RC network can be obtained by designating n=3 to the inventive n-stage RC network of FIG. 15(a) so the output of the inventive 180° phase-shift RC network is 180° phase-shifted.

An inventive 360° phase-shift RC network can be obtained by designating n=6 to the inventive n-stage RC network of FIG. 15(a) so the output of the inventive 360° phase-shift RC network is 360° phase-shifted.

Each of the inventive first type capacitor˜the seventh type capacitor, the first type capacitor assembly˜the fifty-sixth capacitor assembly, and the first type n-stage RC network˜the eighth type n-stage RC network can function as an ac/dc decoupler. For example, an embodiment is shown in FIG. 20 by using n-stage RC network as an ac/dc decoupler. FIG. 20 has shown an electrical power 481 driving a loading 480 having a second upper bound. A n-stage RC network 488 for n≧1 electrically connected in parallel to the loading 480 is for decoupling unwanted ac flowing through the loading line. The n is not limited to any particular number, for example, an embodiment, the n=3.

A TVS 482 is electrically connected in parallel to the loading 480 and the n-stage RC network 488. The TVS 482 has a first upper bound and a first threshold lower than the second upper bound. A voltage from the electrical power 481 exceeding the first threshold of the TVS 482 will go through the TVS 382 to protect the loading 480 at the moment.

A GDT 483 having a second threshold lower than the first upper bound of the TVS 482 is in parallel to the TVS 482 for protecting the TVS 482. When a voltage across the GDT 483 reaching its second threshold will electrically conduct the GDT 483 to save the TVS 382 at that moment.

The n-stage RC network 488 can be any one of the inventive first n-stage RC network ^{˜}eighth n-stage RC network. If the electrically discharge of the GDT 483 is visible, then the GDT 483 has also featured a visible warning to user, for example, if the GDT 483 keeps giving a visible warning for a long period of time, then the TVS 482 may be bad. A diode 484 electrically in series with the TVS 482 may be needed for prohibiting a first DC 485 from flowing backward into the loading 480 or the electrical power 481.

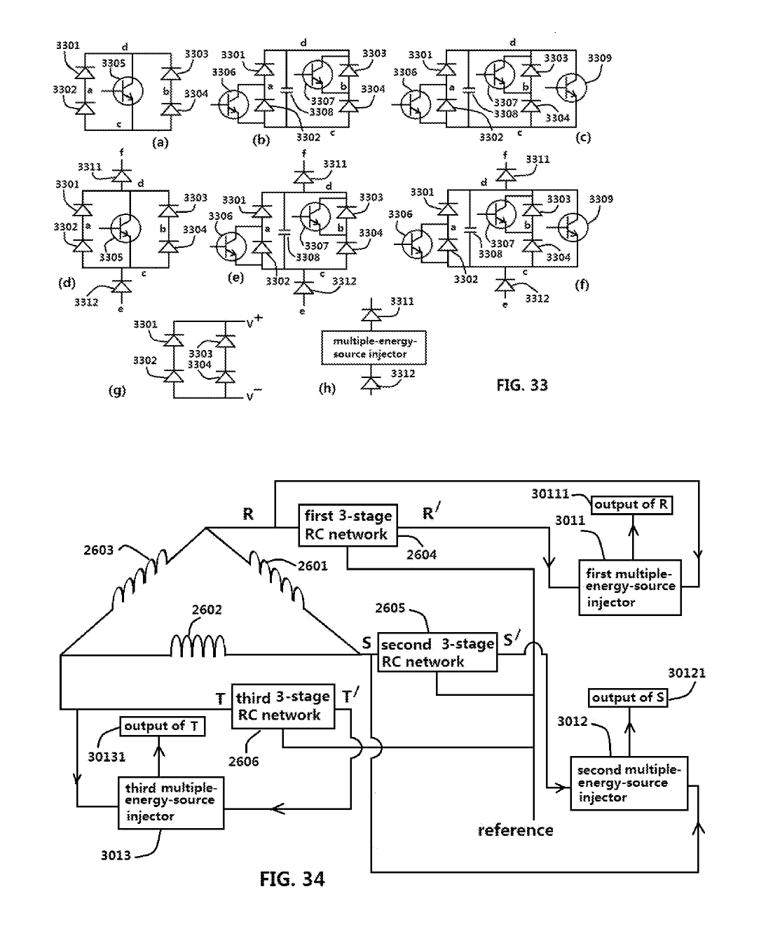

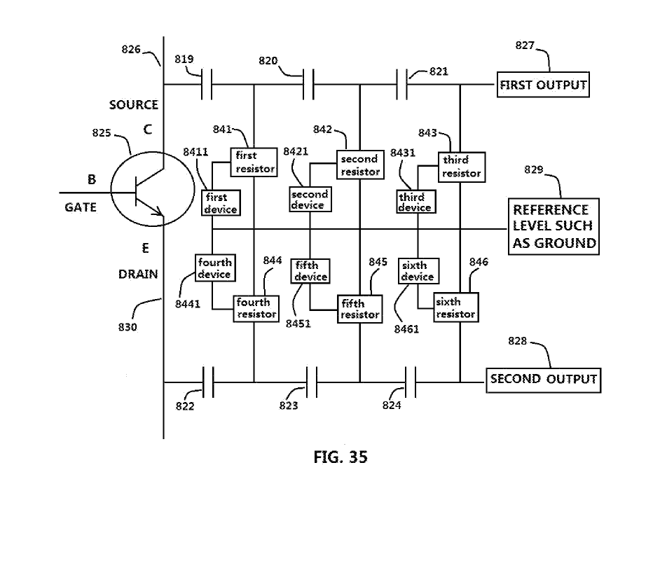

Assuming multiple dc electrical inputs with different voltages inputted into a coil of an inductor, only an electrical input with the highest voltage injects into the coil. Aiming to solve the problem, an inventive multiple-energy-source injector is revealed in the present invention. FIG. 33(g) has shown a prior-art full-bridge rectifier formed by a first circuit formed by a first diode 3301 and a second diode 3302 in same direction electrically connected in series and a second circuit formed by a third diode 3303 and a fourth diode 3304 in same direction electrically connected in series electrically connected in parallel to the first circuit.

An inventive multiple-energy-source injector can be obtained by at least a diode electrically connected in parallel to a transistor with opposite current direction or at least a transistor electrically connected in parallel to the first circuit and the second circuit with opposite current direction of the full-bridge rectifier of FIG. 33(g). A transistor and the diode in parallel with the transistor can be a transistor with its parasitic diode known in the industry.

The inventive multiple-energy-source injector can further comprise a capacitor electrically connected in parallel to the first circuit and the second circuit to increase its performance. For example, a first embodiment of the inventive multiple-energy-source injector, each diode of the full-bridge rectifier of FIG. 33(g) is electrically connected in parallel to a transistor, a second embodiment of the inventive multiple-energy-source injector as shown in FIG. 33(a), a transistor 3305 is electrically connected in parallel to the first circuit and the second circuit of the full-bridge rectifier of FIG. 33(g), a third embodiment of the inventive multiple-energy-source injector as shown in FIG. 33(b), a first transistor 3306 is electrically connected in parallel to the second diode 3302, a second transistor 3307 is electrically connected in parallel to the third diode 3303, and a capacitor 3308 is electrically connected in parallel to the first circuit and the second circuit of the full-bridge rectifier of FIG. 33(g), or a fourth embodiment of the inventive multiple-energy-source injector as shown in FIG. 33(c), a first transistor 3306 is electrically connected in parallel to the second diode 3302, a second transistor 3307 is electrically connected in parallel to the third diode 3303, a third transistor 3309 is electrically connected in parallel to the first circuit and the second circuit, and a capacitor 3308 is electrically connected in parallel to the first circuit and the second circuit of the full-bridge rectifier of FIG. 33(g). A, b, c and d shown in each of FIG. 33(a), FIG. 33(b) and FIG. 33(c) are input points for receiving electrical input.

The inventive multiple-energy-source injectors revealed above can further comprise two diodes and the inventive multiple-energy-source injector and the two diodes are electrically connected in series with each other with the inventive multiple-energy-source injector seated between the two diodes advantaging to increase the number of input points respectively for receiving an electrical input and increase the voltage rating capability for the inventive multiple-energy-source injector as shown in FIG. 33(h). For example, FIG. 33(d) has shown the result if the multiple-energy-source injector of FIG. 33(h) is the multiple-energy-source injector of FIG. 33(a), FIG. 33(e) has shown the result if the multiple-energy-source injector of FIG. 33(h) is the multiple-energy-source injector of FIG. 33(b), FIG. 33(f) has shown the result if the multiple-energy-source injector of FIG. 33(h) is the multiple-energy-source injector of FIG. 33(c), FIG. 33(d) and FIG. 33(e) and FIG. 33(f) have respectively shown six input points a, b, c, d, e and f. The inputs to the inventive multiple-energy-sources injector can be ac or dc and the output of the inventive multiple-energy-sources injector is dc.

Two points with different voltages of the inventive multiple-energy-source injector can be converted into current when a transistor in the multiple-energy-sources injector is turned on to become conductive to electrically connect the two points so currents in same direction respectively converted by multiple inputs can be summed up to an output with a voltage before into a coil of an inductor. The inventive multiple-energy-source injector advantages to modulate multiple electrical inputs with different voltages into an electrical output. A waveform of a signal to control a transistor modulated into the transistor can also relate to the output of the inventive multiple-energy-sources injector. The transistor of the inventive multiple-energy-source injector is not limited to any particular transistor. The transistors of the inventive multiple-energy-sources injector can be independently controlled or controlled by a same controller.

An embodiment of each of the inventive multiple-energy-sources injectors above, input point b can be a rechargeable battery or super capacitor, input point a can be a fuel cell, a solar cell or an electric generator and point f can be an output point for FIG. 33(d), FIG. v33(e) and FIG. 33(f).

Each of the inventive first type capacitor˜the seventh type capacitor, the first type capacitor assembly˜the fifty-sixth capacitor assembly, and the first type n-stage RC network˜the eighth type n-stage RC network can function as an ac/dc decoupler. Ac such as Lenz current presented on two terminals of a transistor can be decoupled by the ac/dc decoupler. An embodiment by using the inventive n-stage RC network as an ac/dc decoupler is shown in FIG. 29(a).

FIG. 29(a) has shown a first n-stage RC network 82511 for n≧1 and a second m-stage RC network 82521 for m≧1 respectively electrically connect in parallel to a first terminal 8251 and a second terminal 8252 of a transistor 825. Ac such as Lenz current produced by the switchings of the transistor 825 respectively presented at the first terminal 8251 and the second terminal 8252 of the transistor 825 can respectively be coupled into the first n-stage RC network 82511 and the second m-stage RC network 82521. Once the ac coupled into each RC network, at least a portion of the ac power will be attenuated or weakened by its damping function so the weaken electrical power can not be strong enough to flow backward to the terminals of the transistor 825.

Two references respectively of the first n-stage RC network 82511 and the second m-stage RC network 82521 can be electrically connected together forming a reference 888. The n and m can be same or different and are respectively not limited to any particular number, for example, an embodiment, n=m=3, meaning both the first n-stage RC network 82511 and the second m-stage RC network 82521 are 180° phase-shift RC networks.

The transistor 825 is not limited to any particular transistor, for example, the transistor 825 can be a bipolar transistor, an insulated-gate bipolar transistor (IGBT), a field-effect transistor (FET), a metal-oxide-semiconductor field-effect transistor (MOSFET), a power FET, or a power MOSFET, etc.

Depending on the type of the transistor, any one of the first terminal and the second terminal of the transistor 825 can be an emitter and the other one of the first terminal and the second terminal of the transistor 825 can be a collector for bipolar transistor and IGBT. Any one of the first terminal and the second terminal of the transistor 825 can be a drain and the other one of the first terminal and the second terminal of the transistor 825 can be a source for FET and MOSFET.

The embodiment of FIG. 29(a) has featured: (1) ac such as Lenz current respectively presented at the two terminals of the transistor 825 can respectively be coupled into the RC networks and at least a portion of the ac power gets electrically dissipated, (2) the output of each RC network respectively as a first output 82512 and a second output 82522 is 180° phase-shifted if n=m=3, which is useful in many applications, and (3) the transistor 825 functions normally or abnormally can be monitored by comparing the waveforms of the first output 82512 of the first n-stage RC network 82511 and the second output 82522 of the second m-stage RC network 82521.

An embodiment about the inventive 180° phase-shift RC network of the n-stage RC network of FIG. 29(a) for n=m=3 is shown in FIG. 22.

The transistor of FIG. 29(a) can be manufactured by integrated circuit process in a form of a 6-terminal IC chip of which three terminals are respectively the first output 82512, the second output 82522, and the reference 888.

The transistor circuit of FIG. 29(a) can be used to construct an inventive active inductance control circuit as shown in FIG. 29(b). FIG. 29(b) has shown a first transistor 827 electrically connected in parallel with at least a portion of the conductive coil 1241 shown as between e and f of a conductive coil 828 of an inductor. When the first transistor 827 is turned on to become conductive current will bypass the portion of between e and f of the conductive coil 828 so the inductance of the inductor drops at the moment.

Actively controlling the transistor or transistors can vary the inductance of the inductor. For example, assuming inductances before and after the detour are respectively expressed by L₁ and L₂, L₁ can be a lot bigger than L₂, or L₂<<L₁ by the active control. The waveform to control the transistor and the duty time of the transistor of the active inductance control circuit of FIG. 29(b) also contribute to the inductance variations of the inductor.

Ac such as Lenz current produced by the switchings of the first transistor 827 can be coupled into a third c-stage RC network 82711 and a fourth d-stage RC network 82721 and at least a portion of the ac power into the RC networks will be attenuated or weakened. The c and d can be same or different, for example, an embodiment, c=d=3.

More than one transistor can be used to the inventive active inductance control circuit. FIG. 29(b) has shown a second transistor 826 electrically connected in parallel with at least a portion of the conductive coil 1241 shown as between g and h of the conductive coil 828 of an inductor. Ac such as Lenz current produced by the switchings of the second transistor 826 can be coupled into a first a-stage RC network 82611 and a second b-stage RC network 82721 and at least a portion of the ac power into the RC networks will be attenuated or weakened. A and b can be same or different, for example, an embodiment, a=b=3.

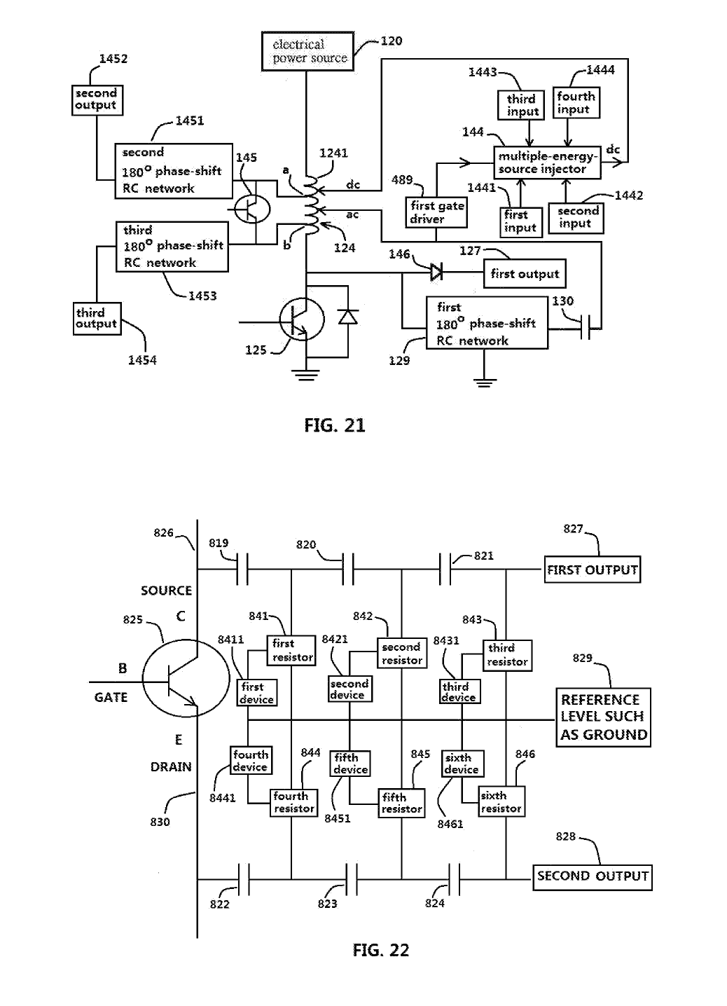

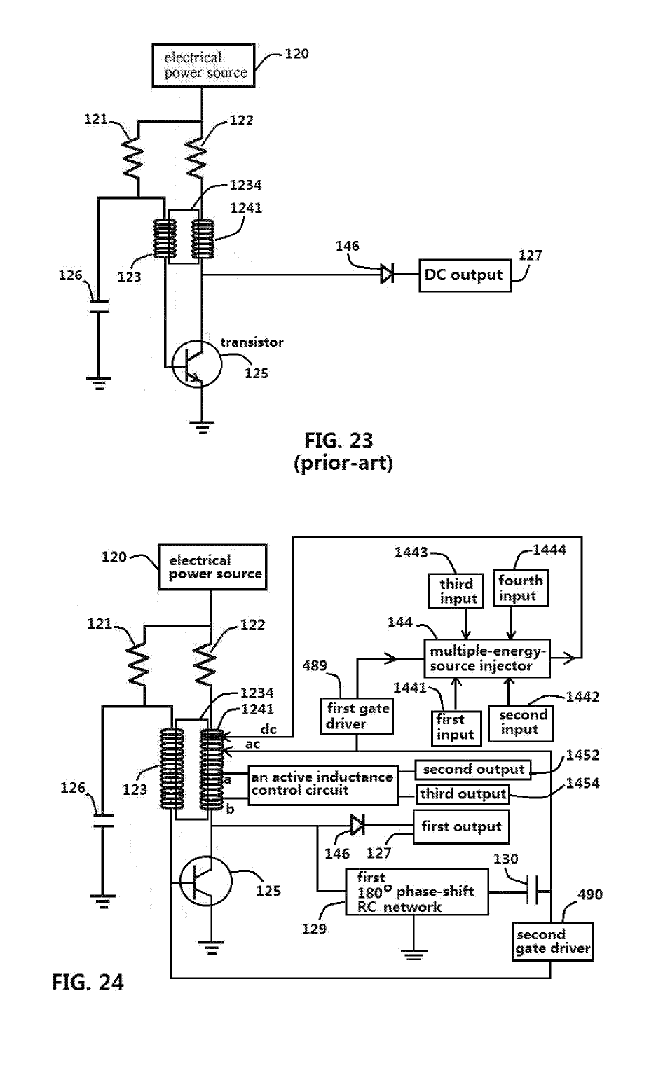

Switching circuit for regulating voltage is a basic circuit seen in many applications. The inventive 180° phase-shift or 3-stage RC network, the inventive multiple-energy-source injector and the inventive active inductance control circuit can be employed into a switching circuit to increase its performance. FIG. 21 has shown a prior-art switching circuit or boost circuit formed by an electrical power source 120, an inductor 124 having a conductive coil 1241 and a first transistor 125 usually came with a parasitic diode electrically connected in series with each other. The switching circuit has a first output 127 taken between the inductor 124 and the first transistor 125 after a diode 146.

A first positive feedback loop is formed by a first 180° phase-shift RC network or third 3-stage RC network 129 electrically connected to between the first transistor 125 and the inductor 124 and the conductive coil 1241. The output of the first 180° phase-shift RC network 129 is 180° shifted in phase with the first transistor 125, in other words, the output of the first 180° phase-shift RC network 129 is positively fedback to go through the inductor 124 when the first transistor 125 is turned on.

An inventive multiple-energy-source injector 144 employed with the switching circuit advantages to modulate multiple electrical inputs with different voltages into a dc electrical power before entering into the switching circuit.

An inventive active inductance control circuit employed with the switching circuit advantages to use the feature of inductance variation of the inductor to increase the performance of the switching circuit.

The 180° shifted ac output of the first 180° phase-shift RC network 129 going through a first gate driver 489 is also used to control a transistor or transistors (not shown in FIG. 21 for the simplication of the drawing) of an inventive multiple-energy-source injector 144 having multiple electrical inputs respectively as a first input 1441, a second input 1442, a third input 1443 and a fourth input 1444. The multiple electrical inputs are modulated by the multiple-energy-source injector 144 into an output with a voltage before being inputted into the conductive coil 1241.

Shown in FIG. 21, the second transistor 145 is electrically connected in parallel to at least a portion of the conductive coil 1241 shown as between a and b of the conductive coil 1241. A second 180° phase-shift RC network 1451 having a second output 1452 is electrically connected in parallel to a first terminal of the second transistor 145 and a third 180° phase-shift RC network 1453 having a second output 1454 is electrically connected in parallel to a second terminal of the second transistor 145. When the second transistor 145 is turned on to become conductive current will bypass the portion of between a and b of the conductive coil 1241 so the inductance of the inductor 124 drops at the moment. The inductance drop at the moment advantages to pull more current out of the electrical power source 120 and the pulled-out bigger current has to go through the conductive coil 1241 of the inductor 124 when the second transistor 145 is turned off to get bigger magnetization on the switching circuit. Besides, if the second transistor 145 is turned on in the on cycle of the first transistor 125, then the pulled-out bigger current from the electrical power source 120, the first output 127, the second output 1452, and the third output 1454 will go through the switching circuit with the first transistor 125 in on state to get the most magnetization on the inductor 124, in other words, the performance of the switching circuit is improved.

Each of the first output 127, the second output 1452, the third output 1454, a battery, a generator, a fuel cell and a solar cell can be any one of the first input 1441, second input 1442, third input 1443 and fourth input 1444 of the multiple-energy-source injector 144.

The multiple-energy-source injector 144 is not limited to any particular multiple-energy-source injector, for example, the multiple-energy-source injector 144 can be any one of FIGS. 33(a), 33(b), 33(c), 33(d), 33(e) and 33(f).

The first transistor 125 of the switching circuit can be controlled by a given signal such as from a PWM controller or the first transistor 125 is a self-excitation switch switched by the charge or the discharge of the capacitor 126 as shown in the blocking oscillator shown in FIG. 24 based on the switching circuit of FIG. 21. FIG. 24 has also featured the 180° shifted ac output of the first 180° phase-shift RC network 129 is also electrically connected to the base or gate of the first transistor 125 as a positive feedback excitation signal to increase its controllability into and out of self-excitation oscillation mode of the blocking oscillator.

For the simplication of the drawing, the second 180° phase-shift RC network 1451, the third 180° phase-shift RC network 1453 and the second transistor 145 shown in FIG. 21 are simply expressed by an active inductance control circuit shown in FIG. 24. The present invention is not limited to any particular form of a blocking oscillator.

Y and Delta (or Δ) transformers or generators are very popular in power circuit. Both Y and Δ transformers are respectively a type of three-phase electric power transformer design respectively conventionally to have R, S, and T terminals.

As discussed in the background of information section, transforming the prior-art electrical power system into the smart grid for both Y and Δ transformers, there is no reference for the simultaneous measurements of the three ac-based phase voltages for both Y and Δ transformers.

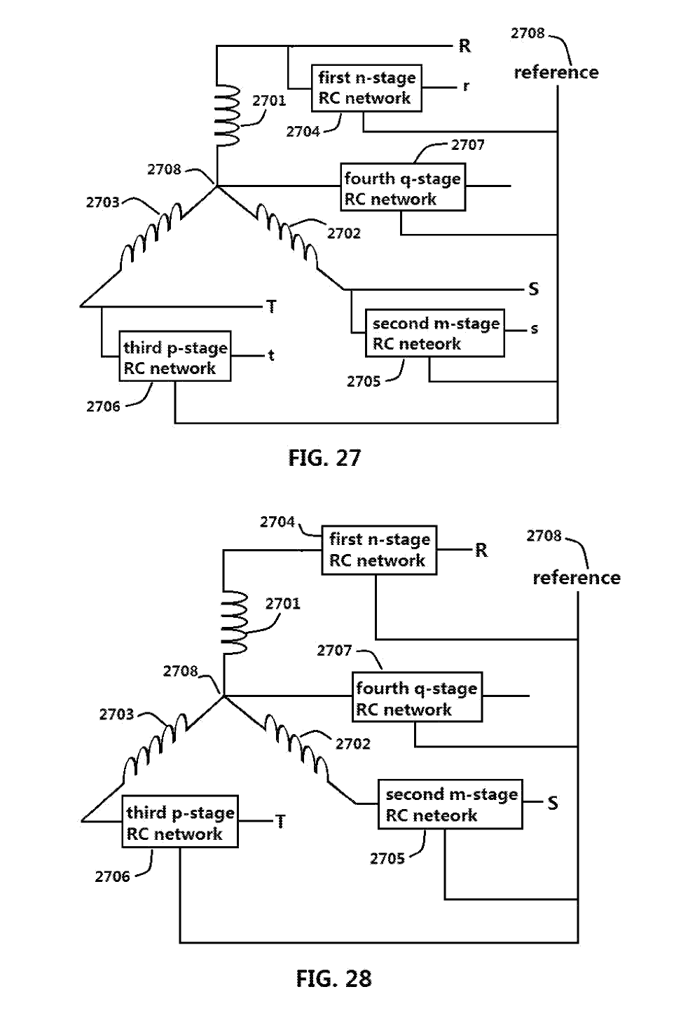

As seen in an embodiment of a Y transformer having a R, S and T terminals shown in FIG. 27, a first n-stage RC network 2704, a second m-stage RC network 2705, and a third p-stage RC network 2706 are respectively electrically connected in parallel to the terminals R, S, and T and a fourth q-stage RC network 2707 is electrically connected to the neutral point 2708 of the Y transformer. All the references respectively of the first n-stage RC network 2704, the second m-stage RC network 2705, the third p-stage RC network 2706, and the fourth q-stage RC network 2707 are electrically connected together to establish a reference 2708 for the Y transformer. A r, s and t are respectively an output of the first n-stage RC network 2704, the second m-stage RC network 2705 and the third p-stage RC network 2706.

Another embodiment of a Y transformer having a R, S and T terminals shown in FIG. 28, a first n-stage RC network 2704, a second m-stage RC network 2705, and a third p-stage RC network 2706 are respectively electrically connected in series with the terminals R, S, and T and a fourth q-stage RC network 2707 is electrically connected to the neutral point 2708 of the Y transformer. All the references respectively of the first n-stage RC network 2704, the second m-stage RC network 2705, the third p-stage RC network 2706, and the fourth q-stage RC network 2707 are electrically connected together to establish a reference 2708 for the Y transformer.

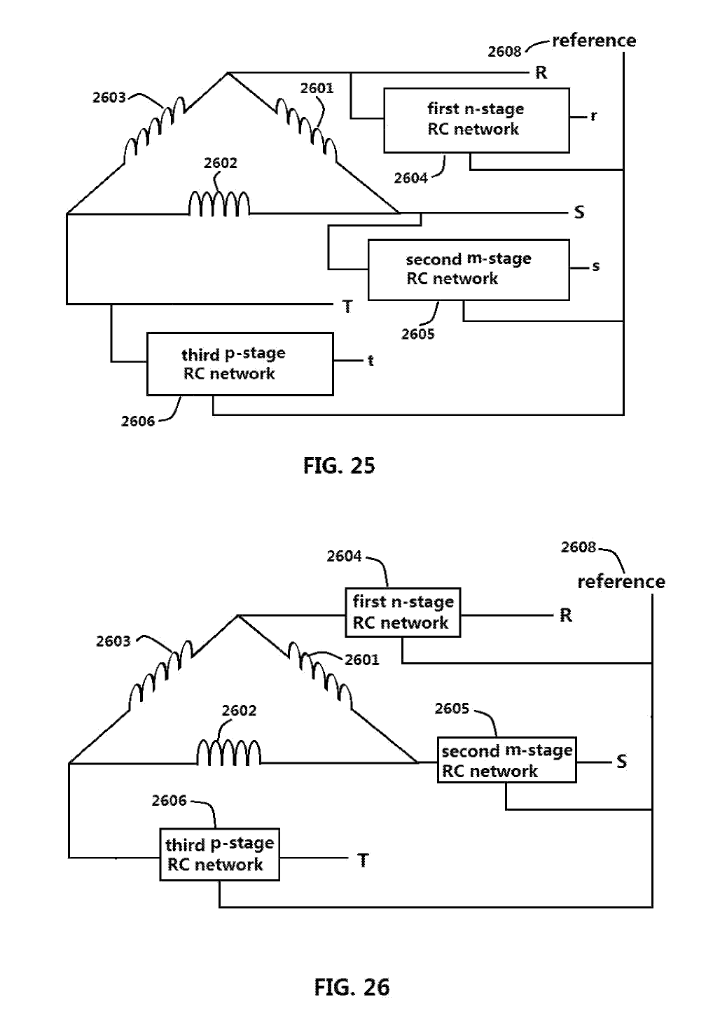

An embodiment of a Δ transformer having a R, S and T terminals shown in FIG. 25, a first n-stage RC network 2604, a second m-stage RC network 2605, and a third p-stage RC network 2606 are respectively electrically connected in parallel to the terminals R, S, and T of the Δ transformer. All the references respectively of the first n-stage RC network 2604, the second m-stage RC network 2605, and the third p-stage RC network 2606 are electrically connected together to establish a reference 2608 for the Δ transformer. A r, s and t are respectively an output of the first n-stage RC network 2604, the second m-stage RC network 2605 and the third p-stage RC network 2606.

An embodiment of a Δ transformer having a R, S and T terminals shown in FIG. 26, a first n-stage RC network 2604, a second m-stage RC network 2605, and a third p-stage RC network 2606 are respectively electrically connected in series to the terminals R, S, and T of the Δ transformer. All the references respectively of the first n-stage RC network 2604, the second m-stage RC network 2605, and the third p-stage RC network 2606 are electrically connected together to establish a reference 2608 for the Δ transformer.

Any one of the first type n-stage RC network, second type n-stage RC network, third type n-stage RC network, fourth type n-stage RC network, fifth type n-stage RC network, sixth type n-stage RC network, seventh type n-stage RC network, and eighth type n-stage RC network for n≧1 can be the first n-stage RC network 2604 or 2704, the second m-stage RC network 2605 or 2705, the third p-stage RC network 2606 or 2706, and the fourth q-stage RC network 2707.

The n, m, p for each of the embodiments of FIG. 25, FIG. 26, FIG. 27, and FIG. 28 are respectively not limited to any particular numbers.

The n, m, p for each of the embodiments of FIG. 25, FIG. 26, FIG. 27, and FIG. 28 can be same or different from each other, for example, an embodiment for each of the embodiments of FIG. 25, FIG. 26, FIG. 27, and FIG. 28, n=m=p=3. The q for each of the embodiments of FIG. 27 and FIG. 28 is not limited to any particular number, for example, an embodiment, q=3.

All the resistance-adjustable resistors or resistor assemblies of the first n-stage RC network, the second m-stage RC network and the third p-stage RC network of Δ transformer can adjust with each other to finalize a same resistance. All the resistance-adjustable resistors or resistor assemblies of the first n-stage RC network, the second m-stage RC network, the third p-stage RC network and the fourth q-stage RC network 2707 of Y transformer can adjust with each other to finalize a same resistance. The R, S and T are known and by properly choosing the resistance of the ZDR or the ZDRs of each resistor to be high enough limits current to flow through each resistor in an expected amount and the PDR or PDRs can further grow bigger to further limit current so that the current can be as small as ignored and a zero or a near zero voltage at the reference can be maintained. The phase voltages of the three phases respectively of the Y and Δ transformers can be simultaneously measured with respective to the reference.

An embodiment for each of the Δ and Y transformers, the first n-stage RC network, the second m-stage RC network and the third p-stage RC network of the Δ transformer are identical and the first n-stage RC network, the second m-stage RC network, the third p-stage RC network, and the fourth q-stage RC network of the Y transformer are identical.

An embodiment for each of the Δ and Y transformers, assuming each resistor has an equivalent ZDR resistance by summing up the resistances of all the ZDRs of each resistor, all the resistors of a transformer have a same equivalent ZDR resistance. An embodiment for each of the Δ and Y transformers, all the resistors of a transformer have a same equivalent ZDR resistance, all the PDRs of the transformer have a same initial setting, and all the NDRs of the transformer have a same initial setting.

The embodiments of the Δ transformers of FIG. 25 and FIG. 26 respectively have an important feature that the reference can be established without needing to break open or re-coil the transformer when transforming a prior-art Δ transformer into a smart grid system, which can save a lot of money with the transforming.

Each of R, S and T of Y and Δ transformers can be processed by an inventive 180° phase-shifter respectively shown as R′, S′, and T′ and each of R and R′, S and S′, and T and T′ can respectively be two inputs of the inventive multiple-energy-source injector to smooth the output of each multiple-energy-source injector so that the R, S, and T output waveforms of Y and Δ transformers can be more continuous.

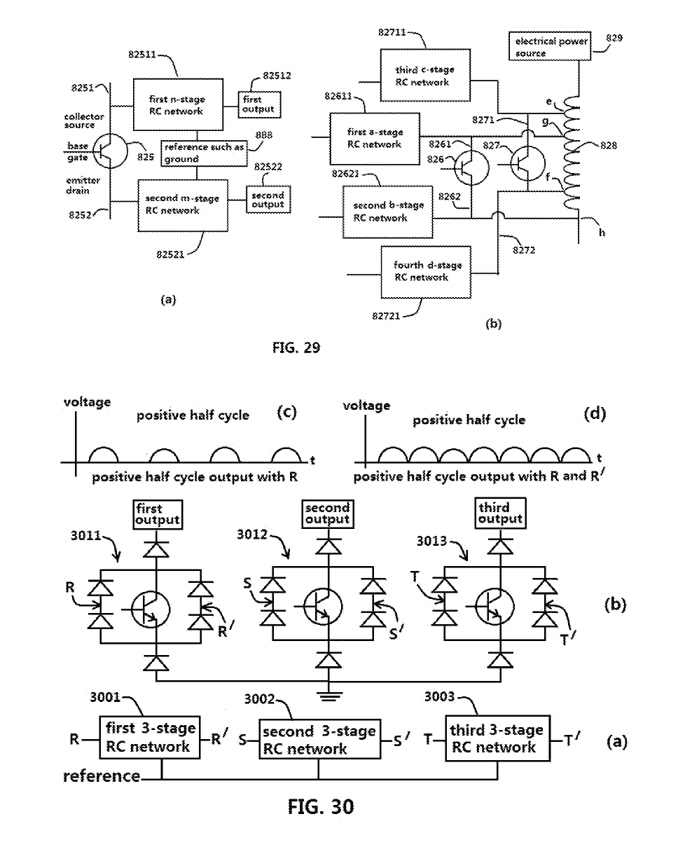

Each of the three outputs R, S and T of Y and Δ transformers and the output of each of the three outputs R, S and T flowing through an inventive 3-stage RC network can respectively be an input of the inventive multiple-energy-source injector advantaging to smooth the electrical power output or make the waveform more continuous. As seen in FIG. 30(a), for convenience, by using the multiple-energy-source injector of FIG. 33(d), assuming R′, S′, and T′ are respectively the output of the R, S and T respectively flowing through a first inventive 3-stage RC network 3001, a second inventive 3-stage RC network 3002, and a third inventive 3-stage RC network 3003. The R and R′ can be two inputs of a first multiple-energy-source injector 3011, the S and S′ can be two inputs of a second multiple-energy-source injector 3012, and the T and T′ can be two inputs of a third multiple-energy-source injector 3013 as shown in FIG. 30(b). FIG. 30(c) has shown an embodiment of a positive half cycle of the R on the diagram of voltage vs time and FIG. 30(d) has shown FIG. 30(c) with the space between two waveforms being filled by the input of the R′ so the power output of FIG. 30(d) is more continuous.

An embodiment is shown in FIG. 34 by using the Δ transformer of FIG. 26. FIG. 34 has shown the R of the Δ transformer and R′, which is the R processed by a first 180° phase-shift RC network 2604, as two inputs to a first multiple-energy-source injector 3011, the S of the Δ transformer and S′, which is the S processed by a second 180° phase-shift RC network 2605, as two inputs to a second multiple-energy-source injector 3012, and the T of the Δ transformer and T′, which is the T processed by a third 180° phase-shift RC network 2606, as two inputs to a inventive multiple-energy-source injector 3013. The waveform of each of an output R 30111 of the first multiple-energy-source injector 3011, an output S 30121 of the second multiple-energy-source injector 3012, and an output T 30131 of the third multiple-energy-source injector 3013 is smoothed or more continuous.

The PDR, the ZDR and the NDR are respectively not limited to any particular PDR, ZDR and NDR, for example, the PDR can be a positive temperature coefficient (or PTC in short) or made of polycrystalline BaTiO₃, the NDR can be a negative temperature coefficient (or NTC in short) or made of sintered metal oxidized materials such as the mixture of Cu, ZnO and Mn₂O₃, and the ZDR can be made of Ni—Mo alloy or SnO₂. All the materials mentioned above can be obtained in the powder form by the sintering process.

1. A RC network, comprising:
n capacitors for n≧1 with each capacitor having an input terminal and an output terminal electrically connected in series with each other forming a RC network receiving terminal for receiving an input into the RC network and a RC network output terminal for outputting an output of the RC network, and
n resistor assemblies with each resistor assembly comprising w resistors for w≧2 electrically connected in parallel with each other with each resistor comprising at least a PDR having different slopes from each other for multiple PDRs, at least a NDR having different slopes from each other for multiple NDRs, and at least a ZDR having different resistances from each other for multiple ZDRs with at least a ZDR having a non-zero resistance electrically connected in series with each other to form a first terminal and a second terminal of each resistor by the serial connections,
wherein each resistor assembly has a first terminal and a second terminal,
the first terminal of each resistor assembly is electrically connected to the output terminal of each capacitor and the second terminals respectively of the n resistor assemblies are electrically connected together.

2. The RC network of claim 1, wherein each resistor has a PDR, a NDR and a ZDR seated between the PDR and the NDR and the first terminal of each resistor is a terminal of the PDR of the resistor.

3. The RC network of claim 1, wherein a plurality of PDRs are grouped together forming a PDR zone, a plurality of NDRs are grouped together forming a NDR zone, and a plurality of ZDRs are grouped together forming a ZDR zone seated between the PDR zone and the NDR zone, the first terminal of each resistor is a terminal of a PDR of the PDR zone of the resistor.

4. The RC network of claim 2, wherein each resistor is in a form of multilayer with each of the PDR, the NDR and the NDR in the form of layer.

5. The RC network of claim 3, wherein each resistor is in a form of multilayer with each of the PDR, the NDR and the NDR in the form of layer.

6. The RC network of claim 4, further comprising a ZDR protection circuit for each resistor, wherein the ZDR protection circuit for each resistor comprises a device having a threshold electrically connected in parallel to its ZDR having a upper bound and NDR, the threshold of the device of the ZDR protection circuit is lower than the upper bound of the ZDR.

7. The RC network of claim 5, further comprising a ZDR protection circuit for each resistor, wherein the ZDR protection circuit for each resistor comprises a device having a threshold electrically connected in parallel to its ZDR zone having a upper bound and NDR zone, the threshold of the device of the ZDR protection circuit is lower than the upper bound of the ZDR zone.

8. The RC network of claim 1, wherein each capacitor is a multilayer capacitor and each multilayer capacitor comprises k PDR layers for k≧2 having different slopes from each other grouped together forming a PDR zone, l PDR layers for l≧2 having different slopes from each other grouped together forming a NDR zone, m ZDR layers for m≧2 having different resistances from each other with at least a ZDR layer having a non-zero resistance grouped together forming a ZDR zone seated between the PDR zone and the NDR zone, a resistance of at least a ZDR layer is high to be an insulator viewed as a dielectric under a dc voltage.

9. The RC network of claim 2, wherein each capacitor is a multilayer capacitor and each multilayer capacitor comprises k PDR layers for k≧2 having different slopes from each other grouped together forming a PDR zone, l PDR layers for ≧2 having different slopes from each other grouped together forming a NDR zone, m ZDR layers for m≧2 having different resistances from each other with at least a ZDR layer having a non-zero resistance grouped together forming a ZDR zone seated between the PDR zone and the NDR zone, a resistance of at least a ZDR layer is high to be an insulator viewed as a dielectric under a dc voltage.

10. The RC network of claim 3, wherein each capacitor is a multilayer capacitor and each multilayer capacitor comprises k PDR layers for k≧2 having different slopes from each other grouped together forming a PDR zone, l PDR layers for l≧2 having different slopes from each other grouped together forming a NDR zone, m ZDR layers for m≧2 having different resistances from each other with at least a ZDR layer having a non-zero resistance grouped together forming a ZDR zone seated between the PDR zone and the NDR zone, a resistance of at least a ZDR layer is high to be an insulator viewed as a dielectric under a dc voltage.

11. The RC network of claim 4, wherein each capacitor is a multilayer capacitor and each multilayer capacitor comprises k PDR layers for k≧2 having different slopes from each other grouped together forming a PDR zone, l PDR layers for l≧2 having different slopes from each other grouped together forming a NDR zone, m ZDR layers for m≧2 having different resistances from each other with at least a ZDR layer having a non-zero resistance grouped together forming a ZDR zone seated between the PDR zone and the NDR zone, a resistance of at least a ZDR layer is high to be an insulator viewed as a dielectric under a dc voltage.

12. The RC network of claim 5, wherein each capacitor is a multilayer capacitor and each multilayer capacitor comprises k PDR layers for k≧2 having different slopes from each other grouped together forming a PDR zone, l PDR layers for l≧2 having different slopes from each other grouped together forming a NDR zone, m ZDR layers for m≧2 having different resistances from each other with at least a ZDR layer having a non-zero resistance grouped together forming a ZDR zone seated between the PDR zone and the NDR zone, a resistance of at least a ZDR layer is high to be an insulator viewed as a dielectric under a dc voltage.

13. The RC network of claim 6, wherein each capacitor is a multilayer capacitor and each multilayer capacitor comprises k PDR layers for k≧2 having different slopes from each other grouped together forming a PDR zone, l PDR layers for l≧2 having different slopes from each other grouped together forming a NDR zone, m ZDR layers for m≧2 having different resistances from each other with at least a ZDR layer having a non-zero resistance grouped together forming a ZDR zone seated between the PDR zone and the NDR zone, a resistance of at least a ZDR layer is high to be an insulator viewed as a dielectric under a dc voltage.

14. The RC network of claim 7, wherein each capacitor is a multilayer capacitor and each multilayer capacitor comprises k PDR layers for k≧2 having different slopes from each other grouped together forming a PDR zone, l PDR layers for l≧2 having different slopes from each other grouped together forming a NDR zone, m ZDR layers for m≧2 having different resistances from each other with at least a ZDR layer having a non-zero resistance grouped together forming a ZDR zone seated between the PDR zone and the NDR zone, a resistance of at least a ZDR layer is high to be an insulator viewed as a dielectric under a dc voltage.

15. The RC network of claim 7, wherein all the resistor assemblies are identical.

16. The RC network of claim 14, wherein all the resistor assemblies are identical.

17. The RC network of claim 15, wherein the RC network output terminal is 180° phase shifted for n=3.

18. The RC network of claim 16, wherein the RC network output terminal is 180° phase shifted for n=3.

19. The RC network of claim 13, wherein the RC network output terminal is 360° phase shifted for n=6.

20. A RC network, comprising:
n capacitors for n≧1 with each capacitor having an input terminal and an output terminal electrically connected in series with each other forming a RC network receiving terminal for receiving an input into the RC network and a RC network output terminal for outputting an output of the RC network, and
n resistor with each resistor comprising at least a PDR for having different slopes from each other, at least a NDR having different slopes from each other, and at least a ZDR having different resistances from each other with at least a ZDR having a non-zero resistance electrically connected in series with each other to form a first terminal and a second terminal of each resistor by the serial connections,
wherein each resistor has a first terminal and a second terminal, the first terminal of each resistor is electrically connected to the output terminal of each capacitor and the second terminals respectively of the n resistors are electrically connected together.
